(19) United States
(12) Patent Application Publication
(10) Pub. No.: US 2007/0290300 A1
(43) Pub. Date: Dec. 20, 2007

(54) Semiconductor device and method for manufacturing same

(75) Inventor: Masaru Kawakami, Kanagawa (JP)

Correspondence Address: ROBERT J. DEPKE;LEWIS T. STEADMAN, ROCKEY, DEPKE & LYONS, LLC, SUITE 5450 SEARS TOWER, CHICAGO, IL, 60606-6306, US

(73) Assignee: SONY CORPORATION

(21) Appl. No.: 11/731,951

(22) Filed: Apr. 2, 2007

(30) Foreign Application Priority Data
May 22, 2006 (JP) P2006-141130

(51) Int. Cl. H01L 21/822; H01L 29/40

(52) U.S. Cl. 257/621; 438/109; 257/E21.614; 257/E23.019

(57) ABSTRACT

Herein disclosed a semiconductor device in which a semiconductor chip is mounted over a substrate, the device including a plurality of through-interconnects configured to be formed inside each of through-holes that penetrate the substrate and be led from the semiconductor chip to a face of the substrate on an opposite side of the semiconductor chip.

### CROSS REFERENCES TO RELATED APPLICATIONS

The present invention contains subject matter related to Japanese Patent Application JP 2006-141130 filed with the Japan Patent Office on May 22, 2006, the entire contents of which being incorporated herein by reference.

### BACKGROUND OF THE INVENTION

1. Field of the Invention

The present invention relates to a semiconductor device having, inside a through-hole formed in a substrate, a through-interconnect that penetrates the substrate from the front face to the back face thereof, and particularly to a semiconductor device in which plural through-interconnects are formed inside a through-hole and to a method for manufacturing the same.

2. Description of the Related Art

For reduction in the size, weight, power consumption, and costs of electronic apparatuses such as portable apparatuses, system-in-package (SiP) techniques, in which plural chips, passive elements and so on are assembled in one package, have been widely employed.

In three-dimensional (3D) mounting for realization of the SiP, connection along the 3D directions is made in a package through wire bonding between chips or between a chip and an interposer substrate. However, the wire bonding involves the following problems: (1) it is difficult to stack plural chips having the same size; (2) a larger wiring length of the wire bonding leads to a higher inductance, and hence makes it difficult to ensure high-speed signal transmission between chips; and (3) a larger number of chips assembled in a package or a larger number of terminals of a logic LSI mounted in a package leads to a much larger number of interconnects in the package, and hence makes it difficult to realize connection through the wire bonding.

The SiP has a disadvantage of being inferior to a system-on-chip (SoC) in the speed of signal transmission between chips. In the SoC, necessary functions are integrated on a one-chip semiconductor substrate for realization of higher performance, smaller size, and smaller weight of digital apparatuses.

Among methods for interconnection between chips, other than the wire bonding, are flip-chip connection and connection by through-electrodes. In the flip-chip connection, circuitry planes of chips are made to face each other and connected to each other through bumps. The through-electrode is formed by burying a metal such as Cu in a through-hole that penetrates a chip from the circuitry plane (active surface) to the back face thereof. In the connection with the through-electrodes, interconnects are vertically formed in a chip, and therefore connection via the shortest distance can be made between chips and between a chip and an interposer. Consequently, extremely short interconnect length can be achieved, which allows shortening in the interconnect delay time.

Various semiconductor devices formed by three-dimensionally stacking semiconductor chips have been known well.

In a document titled “Si kantsuu chip no kouzou kakumei” (“revolution in the structure of Si-penetrating chips” in English, Nikkei Electronics (Japanese Magazine), Issued on Oct. 10, 2005, p. 81-99 (abstract, FIG. 1 in the second section), hereinafter Non-Patent Document 1), there is a description relating to a Si-penetrating electrode and a wireless communication technique for realization of transmission paths penetrating a chip.

Formation of a through-hole includes, in rough classification, a dry etching step for opening a hole in a Si substrate and an electrode forming step of filling the hole with a conductive material (e.g., Cu, W, or Poly-Si). Applying a micro-processing technique to the hole opening can form a small through-hole with a diameter of several micrometers.

The wire bonding and the flip-chip connection involve limitation on the number of interconnects and the number of chips that can be connected to each other. In contrast, in the connection with through-electrodes, plural chips can be connected via several thousands of through-electrodes. Therefore, enhanced speed of signal transmission between chips can be achieved, which can eliminate the disadvantage of existing SiP.

A claim in Japanese Patent Laid-open No. Sho 59-222954 (hereinafter Patent Document 1) titled “Sekisou handoutai shuuseki kairo oyobi sono seihou” (“Stacked semiconductor integrated circuit and method for manufacturing same” in English) discloses an integrated circuit obtained by stacking at least two active substrates in which an element group is formed on at least one major face of a semiconductor substrate. This integrated circuit is distinctive in that a connection part for the active substrates is formed of a solder pad and an intermediary solder layer that face each other, and in that a through-hole of which inner wall is covered by an insulating film and a conductive film is provided on at least one side of the solder pad.

Japanese Patent Laid-open No. Hei 5-63137 (hereinafter Patent Document 2, Paragraphs 0011 to 0020) titled “Handoutai souchi” (“Semiconductor device” in English) includes the following description.

The invention of Patent Document 2 aims to provide a chip-on-chip structure for which alignment in stacking of chips is easy and stacking of a large number of chips is allowed.

According to Patent Document 2, this aim is achieved by a semiconductor device obtained by stacking plural semiconductor chips. In this device, the chip has electrodes on the front and back faces thereof, and the electrodes are connected to each other via a through hole penetrating the chip. The chips are connected to each other through the electrode.

In the invention of Patent Document 2, an electrode that is connected via a through-hole penetrating a chip to an electrode for interconnection between chips, formed on the front face of the chip. This allows a large number of chips to be stacked in such a way that the front face and the front face of the chips, the front face and the back face of the chips, and the back face and the back face of the chips are made to face each other.

Because electrodes for interconnection between chips exist on both the faces of a chip, alignment of chip positions is easy for each combination of the front and back faces of chips, and hence stacking of a large number of chips is permitted.

FIG. 23A is a sectional view for explaining one embodiment of the invention of Patent Document 2, and corresponds to FIG. 1 in Patent Document 2. In FIG. 23A, reference numerals 201, 211, and 212 denote a first chip, an internal circuit, and a through-hole filled with a conductive material, respectively. Numerals 213, 214, and 215 denote an insulating film such as an SiO₂ or SiON film, an electrode for interconnection between chips, and a bump, respectively. Numerals 202, 221, and 222 denote a second chip, an internal circuit, and a through-hole filled with a conductive material, respectively. Numerals 223, 224, and 225 denote an insulating film such as an SiO₂ or SiON film, an electrode for interconnection between chips, and a bump, respectively. Numerals 226, 208, and 281 denote an external connection electrode or interconnection electrode, a film for tape-automated bonding (TAB), and an interconnect that is formed on the TAB film and connected to an external terminal, respectively.

The through-hole is opened by anisotropic etching, and the insulating film such as an SiO₂ or SiON film is deposited by chemical vapor deposition (CVD) on the sidewall of the opened through-hole. For the anisotropic etching of the through-hole, a film having a high selectivity with respect to Si is patterned by lithography, so that this pattered high-selectivity film is used as the mask. Filling the through-hole with a conductive material is carried out through selective CVD of tungsten or the like or electrolytic plating.

Japanese Patent Laid-open No. 2001-127243 (hereinafter Patent Document 3, Paragraphs 0007 to 0024, FIGS. 1 to 5) titled “Sekisou handoutai souchi” (“Stacked semiconductor device” in English) includes the following description.

In the invention of Patent Document 3, through-electrodes and interconnection electrodes common to chips are formed on each chip, and these electrodes are connected to each other via any optional interconnect pattern. According to Patent Document 3, this structure enhances the flexibility of the interconnect pattern for interconnection between semiconductor chips, and eliminates the need to considerably change the arrangement design of electrodes for interconnection between semiconductor chips for every stacked semiconductor device, to thereby provide a stacked semiconductor device of which high-mix low-volume production is facilitated.

Specifically, the invention of Patent Document 3 is to provide a stacked semiconductor device having plural stacked semiconductor chips. The semiconductor chip has a through-electrode provided to penetrate the semiconductor chip, a first electrode provided on the front face of the semiconductor chip, and a second electrode provided on the back face of the semiconductor chip. Furthermore, the semiconductor chip has interconnect patterns that are provided on the front and back faces of the semiconductor chip and selectively connect the first and second electrodes via the through-electrode. Through stacking of the semiconductor chips, the first electrode on the lower semiconductor chip is connected to the second electrode on the upper semiconductor chip.

In the stacked semiconductor device of Patent Document 3, plural first electrodes and plural second electrodes may be arranged in accordance with a predetermined arrangement form on the front and back faces of a semiconductor chip. Specifically, the predetermined arrangement form may be a matrix form.

Furthermore, in the stacked semiconductor device of Patent Document 3, the first electrode may be a protruding electrode, and the second electrode may be a pad electrode.

FIGS. 21A, 21B, and 21C correspond to FIGS. 1, 2, and 3, respectively, in Patent Document 3. FIGS. 22A and 22B correspond to FIGS. 4 and 5, respectively, in Patent Document 3. These diagrams explain the first embodiment of the invention of Patent Document 3.

FIG. 21A, which corresponds to FIG. 1 in Patent Document 3, is a perspective view showing the form of the first embodiment of a semiconductor chip included in a stacked semiconductor device. FIG. 21B, which corresponds to FIG. 2 in Patent Document 3, is a perspective view obtained by viewing the semiconductor chip shown in FIG. 21A from the back side of the chip. FIG. 21C, which corresponds to FIG. 3 in Patent Document 3, is an enlarged sectional view showing major part of the semiconductor chip shown in FIG. 21A.

FIG. 22A is an explanatory diagram showing a connection example in which semiconductor chips having the same structure as that of the semiconductor chip shown in FIG. 21A are vertically stacked. FIG. 22B is also an explanatory diagram showing a connection example in which semiconductor chips having the same structure as that of the semiconductor chip shown in FIG. 21A are vertically stacked.

As shown in FIGS. 21A, 21B, and 21C, a semiconductor chip 101 for constructing a stacked semiconductor device includes through-electrodes 102 that penetrate the semiconductor chip 101, protruding electrodes (first electrodes) 103 provided on the front face of the semiconductor chip 101, and pad electrodes (second electrodes) 104 provided on the back face of the semiconductor chip 101. Furthermore, the semiconductor chip 101 has interconnect patterns 105a and 105b that are provided on the back face and the front face, respectively, of the semiconductor ship 101 and selectively connect the protruding electrode 103 and the pad electrode 104 via the through-electrode 102. When the semiconductor chips having the above-described structure are stacked, the protruding electrodes on the lower semiconductor chip are connected to the pad electrodes on the upper semiconductor chip.

In particular, as shown in FIG. 21C, the formation positions of the protruding electrodes 103 are in face-to-face with those of the pad electrodes 104 across the semiconductor chip 101. In contrast, as shown in FIG. 21C, the formation positions of the through-electrodes 102 are different from those of the protruding electrodes 103 and the pad electrodes 104. Therefore, the protruding electrodes 103 and the pad electrodes 104 are coupled to the through-electrodes 102 not directly but via the interconnect patterns 105a and 105b.

In the example in FIG. 21C, for coupling between the pad electrode 104 and the protruding electrode 103, the interconnect pattern 105a is provided between the pad electrode 104 and the through-electrode 102, and the interconnect pattern 105b is provided between the protruding electrode 103 and the through-electrode 102. However, as described later, whether to provide the interconnect patterns 105a and 105b is determined depending on selection as to which of protruding electrodes and pad electrodes are electrically coupled for connection to another semiconductor chip. Therefore, the arrangement of the interconnect patterns 105a and 105b is not necessarily limited to the arrangement shown in FIG. 21C.

Furthermore, in FIG. 21C, reference numeral 108 denotes an insulating film that electrically insulates the semiconductor chip 101 from the through-electrodes 102, the protruding electrodes 103, the pad electrodes 104, and the interconnect patterns 105a and 105b. Numeral 107 denotes a protective film for the semiconductor chip 101. The protective film 107 is provided on both the front and back faces of the semiconductor chip 101. However, apertures are ensured only at the formation positions of the protruding electrodes 103 and the pad electrodes 104, and thus the protruding electrodes 103 and the pad electrodes 104 are exposed to the external of the semiconductor chip 101.

As shown in FIG. 21A, on the front-face side of the semiconductor chip 101, the protruding electrodes 103 arranged in a matrix with a constant pitch are exposed. Furthermore, as shown in FIG. 21B, on the back-face side of the semiconductor chip 101, the pad electrodes 104 arranged in a matrix are exposed similarly.

A description will be made below based on FIG. 22A about a connection structure between semiconductor chips, obtained when the above-described semiconductor chips shown in FIGS. 21A, 21B, and 21C are stacked. FIG. 22A shows a connection example in which the semiconductor chip 101 and a semiconductor chip 121 having the same electrode structure and the same electrode arrangement are stacked, and a signal input from a pad electrode 104a on the semiconductor chip 101 is transmitted to a through-electrode 122a of the semiconductor chip 121.

In the connection example shown in FIG. 22A, there is a need to electrically couple the pad electrode 104a of the semiconductor chip 101 to a protruding electrode 103a of the semiconductor chip 101. Therefore, the pad electrode 104a is coupled to a through-electrode 102a via the interconnect pattern 105a, and the through-electrode 102a is coupled to the protruding electrode 103a via the interconnect pattern 105b. In the upper semiconductor chip 121, a pad electrode 124a in contact with the protruding electrode 103a of the semiconductor chip 101 is coupled to the through-electrode 122a via an interconnect pattern 125a.

The protruding electrodes 103a and 103b of the semiconductor chip 101 are bonded to the pad electrodes 124a and 124b of the semiconductor chip 121 through any of the following bonding methods at the time of stacking of the semiconductor chips 101 and 121: heat melting of the electrode materials; solid-phase diffusion bonding through breaking of the surface barrier film by an external force; and pressure bonding through curing shrinkage of resin interposed between the chips.

Due to the connection in the above-described manner, a signal input from a mounting substrate or another semiconductor chip (neither not shown) below the semiconductor chip 101 to the pad electrode 104a is transmitted via the interconnect pattern 105a, the through-electrode 102a, the interconnect pattern 105b, the protruding electrode 103a, the pad electrode 124a, and the interconnect pattern 125a to the through-electrode 122a of the upper semiconductor chip 121. Furthermore, the signal transmitted to the through-electrode 122a is sent via a circuit (not shown) to the internal circuit (not shown) of the semiconductor chip 121.

FIG. 22B shows another connection example in which different signals are input to the pad electrodes 104a and 104b, respectively, of the lower semiconductor chip 101. Similarly to FIG. 22A, the signal input from the pad electrode 104a is transmitted via the interconnect pattern 105a, the through-electrode 102a, the interconnect pattern 105b, the protruding electrode 103a, the pad electrode 124a, and the interconnect pattern 125a to the through-electrode 122a of the upper semiconductor chip 121. In contrast, the signal input from the pad electrode 104b is transmitted via an interconnect pattern 105c, a through-electrode 102b, an interconnect pattern 105d, a protruding electrode 103b, a pad electrode 124b, an interconnect pattern 125c, a through-electrode 122b, and an interconnect pattern 125d to a protruding electrode 123a of the upper semiconductor chip 121, followed by being transmitted to a further upper semiconductor chip (not shown).

That is, in the invention of Patent Document 3, the arrangement form of electrodes is set to a certain form (e.g., a matrix form) irrespective of whether or not the electrodes are utilized for connection between semiconductor chips, and interconnect patterns are applied only to the electrodes necessary for the connection between semiconductor chips for signal transmission. According to Patent Document 3, this scheme enhances the flexibility of interconnect patterns for connection between semiconductor chips, and eliminates the need to considerably change the arrangement design of electrodes for connection between semiconductor chips for every stacked semiconductor device. These advantages facilitate high-mix low-volume production of the stacked semiconductor device.

In a document titled “Sanjigen jissou ni mochiiru chip kantsuu denkyoku keisei gijutsu” (“Technique for forming chip-penetrating electrodes used for three-dimensional mounting” in English, Tomisaka et al., Denso Technical Review, 6(2), 78-84 (2001), Sections 2 to 4, hereinafter Non-Patent Document 2), the following features are described: (1) it is possible to form a hole with an aperture diameter of 10 μm and a depth of 70 μm through silicon dry etching and form a barrier metal and a seed layer in the hole through CVD; (2) the size of a void remaining in the center part of the hole can be reduced to 2 μm based on a clearly-shown scheme for completely filling the hole having the 10 μm diameter and the 70 μm depth (aspect ratio of 7) by using Cu electrolytic plating.

Furthermore, in a document titled “Silicon kiban e keisei shia kou aspect hi kantsuu haisen” (“High-aspect-ratio through-interconnect formed in silicon substrate” in English, Suemasu et al., Fujikura Technical Review, No. 102, 53-57 (2002), Section 2, hereinafter Non-Patent Document 3), results of trial manufacturing of through-interconnects (having a diameter of 15 μm, an aspect ratio of 35, the maximum formation density of 500/cm², and a breakdown voltage of 500 V or higher) are shown. These through-holes are formed by burying a metal in a silicon substrate having a thickness of about 500 μm by using an optically-assisted electrolytic etching method and a molten-metal suction method.

In addition, as described in a document titled “handoutai fuushi zairyou no gijutsu doukou” (“Technical trends of semiconductor sealing materials” in English, Fukui, Matsushita Electric Works Technical Report, February, 2004, 9-16 (FIGS. 9 and 12, and Table 6 hereinafter Non-Patent Document 4), the following sealing methods are well known: a method referred to also as a side-fill method; a no-flow-type underfill method (referred to also as a no-flow underfill method); and a method referred to as an NCP process. In the side-fill method, underfill sealing is carried out based on the capillary phenomenon after a chip and a substrate are connected to each other by a flip chip bonder. In the no-flow-type underfill method, resin is supplied to a substrate in advance, and then underfill sealing is completed simultaneously with flip chip connecting in a reflow step subsequent to chip mounting. In the NCP process, a chip is mounted after a liquid resin called a non-conductive paste (NCP) material is applied on a substrate. Subsequently, mechanical bonding between metals is fixed through short-time pressure heating, followed by after-curing.

Japanese Patent Laid-open No. 2005-243689 (hereinafter Patent Document 4, Paragraphs 0013; 0014, and 0017 to 0029, FIG. 1) titled “Handoutai chip no seizou houhou oyobi handoutai souchi” (“Method for manufacturing semiconductor chip and semiconductor device” in English) includes the following description.

An aim of the invention of Patent Document 4 is to provide a method for manufacturing a semiconductor chip including a semiconductor element that is not affected by heat treatment in formation of an insulating film for insulating a through-electrode from a semiconductor substrate, and hence has favorable characteristics.

According to the invention of Patent Document 4, there is provided a method for manufacturing a semiconductor chip obtained by forming plural semiconductor elements and through-electrodes insulated by an insulating film on a semiconductor substrate. This method is distinctive in that the step of depositing the insulating film is carried out before the step of forming the semiconductor elements.

FIGS. 23B(a) to (f) are sectional views for explaining steps for manufacturing a semiconductor chip according to the first embodiment of the invention of Patent Document 4, and correspond to FIG. 1 in Patent Document 4.

As shown in FIG. 23B(f), a semiconductor chip 350 manufactured by the following manufacturing method includes plural semiconductor elements 306 (only one element is shown in the drawing) formed on a surface of a silicon substrate 310. Furthermore, the semiconductor chip 350 includes a sidewall insulating film 321, an interlayer insulating film 323, and a metal film 332 that are sequentially formed on the inner wall of a through-hole penetrating the silicon substrate 310. In addition, the semiconductor chip 350 includes a through-electrode 333a composed of a conductive material provided in the through-hole.

To manufacture this semiconductor chip 350, as shown in FIG. 23B(a), initially a recess 320 having a predetermined depth is formed in the silicon substrate 310 (hereinafter, referred to simply as “substrate 310”) with use of a resist 311 formed on the substrate 310 as the mask.

Subsequently, as shown in FIG. 23B(b), an element covering film 321a is formed on a part of the surface of the substrate 310, specifically, formed at the position corresponding to the region on which the semiconductor element 306 is to be formed. Thereafter, the sidewall insulating film 321 composed of an insulating material is formed on the entire inner wall of the recess 320 and the entire surface of the substrate 310.

Referring next to FIG. 23B(c), the element covering film 321a formed in the previous step is removed to form an aperture in the sidewall insulating film 321. Subsequently, on the exposed surface of the substrate 310, the semiconductor element 306 such as a MOS transistor or bipolar transistor is formed. Thereafter, the interlayer insulating film 323 is formed to cover the semiconductor element 306. As described above, the semiconductor element 306 is formed after the formation of the sidewall insulating film 321. Therefore, the semiconductor element 306 is formed without being affected by heat treatment in the formation of the sidewall insulating film 321.

Subsequently, as shown in FIG. 23B(d), the recess 320 is filled with a conductive material. As the conductive material, a metal such as aluminum, tungsten, copper, silver, or gold can be used. As a filling method, any of plating, metal CVD, and a method of applying a metal-dispersed resin paste is available. In the case of using plating, a metal serving as the base of the plating is deposited by sputtering or the like, and then electrolytic plating is carried out, which allows the recess 320 to be filled with the conductive material.

In this method, the metal film 332 (e.g., a Ti/TiN film) is deposited on the entire surface of the interlayer insulating film 323 by sputtering, and then a through-electrode film 333 is formed on the entire surface of the metal film 332 by electrolytic plating so that the recess 320 is filled with the conductive material. In the case of forming a Ti/TiN film as the metal film 332, sputtering may be carried out at a substrate temperature of 50° C. with a power input condition of Ti/TiN=12 kW/20 kW.

Referring next to FIG. 23B(e), the substrate 310 is polished by e.g. chemical mechanical polishing (CMP) from the front-face side, on which the semiconductor element 306 is formed, to thereby remove unnecessary parts of the through-electrode film 333 and the metal film 332.

Subsequently, as shown in FIG. 23B(f), the substrate 310 is polished from the back-face side, so that the thickness of the substrate 310 is decreased and the conductive material of the through-electrode film 333 provided in the recess 320 is exposed at the back-face side of the substrate 310. This forms the through-electrode 333a penetrating the silicon substrate 310.

Through the above-described series of steps, the semiconductor chip 350 having the through-electrode 333a is manufactured.

A document titled “20 μm pitch bisai Cu bump setsugou niyoru sanjigen chip jissou” (“3D chip stacking utilizing 20 μm-pitch micro Cu bump interconnection” in English, Tanida et al., Journal of Japan Institute of Electronics Packaging, 8(4), 308-317 (2005), Abstract, hereinafter Non-Patent Document 5) includes the following description.

In ASET, in the project “Chou koumitsudo densi SI gijutsu no kenkyuu kaihatsu kikou” (“Organization for research and development of ultra-high-density electronic SI technique” in English) started from 1999, development has been advanced on a 3D chip stacked structure as an SiP suitable to achieve higher density and speed. This structure arises from stacking of chips in which micro Cu through-electrodes with a 20 μm pitch are formed inside Si. In the manufacturing procedure for the structure, a chip stacking process is an important technique. Studies therefore were made on micro Cu bump interconnection as an industrial stacking process. In this process, without formation of bumps on the back faces of chips, Cu through-electrodes are connected to each other through Cu—Sn diffusion. In these studies, the connection reliability and the electric characteristics of a through-electrode circuit in the 3D chip stacked structure were evaluated. These studies showed that the Cu—Sn diffusion could be controlled even in a small area, i.e., a 20 μm pitch area, and that favorable interconnection strength could be achieved by employing an intermetallic compound Cu₃Sn as the interconnection interface material. As a result, it was confirmed that a four-chip stacked structure could show such connection reliability as to withstand 1500 or more cycles of a temperature cycling test (TCT). Furthermore, with use of a daisy chain circuit and a ring oscillator feedback circuit including the Cu through-electrode structure, the DC resistance and the signal delay time were measured. As a result, the resistance rise per one layer of the through-electrode circuit including the Cu bump interconnection part was 15.4 mΩ, and the signal delay time was 0.9 ps, which showed that the Cu through-electrode structure was sufficiently available as an inter-chip high-speed signal circuit at a GHz level.

Japanese Patent Laid-open No. 2006-12889 (hereinafter Patent Document 5, Paragraphs 0029 to 0031, and 0037 to 0056, FIG. 2) titled “Handoutai chip no seizou houhou oyobi handoutai souchi no seizou houhou” (“Method for manufacturing semiconductor chip and method for manufacturing semiconductor device” in English) includes the following description.

An aim of the invention of Patent Document 5 is to provide a method for manufacturing a semiconductor chip that is allowed to have enhanced productivity through shortening of the formation time of through-holes for through-electrodes. Another aim thereof is to provide a method for manufacturing a semiconductor device, utilizing such a manufacturing method for a semiconductor chip. Further another aim thereof is to provide a semiconductor chip and a semiconductor device that are allowed to have enhanced reliability through the use of these manufacturing methods.

According to the invention of Patent Document 5, there is provided a method for manufacturing a semiconductor chip having a through-electrode penetrating a semiconductor substrate. The method includes the step of forming a first trench by anisotropic etching from one face of the semiconductor substrate, and the step of forming a second trench in communication with the first trench by anisotropic etching from the face opposite to the one face of the semiconductor substrate. The method includes also the step of forming an insulating film composed of an insulating material on the inner wall of a through-hole arising from the communicating of the first trench with the second trench, and the step of filling the through-hole in which the insulating film has been formed with a conductive material to thereby form the through-electrode.

Furthermore, in a method for manufacturing a semiconductor device according to the invention of Patent Document 5, plural semiconductor chips manufactured by the above-described method for manufacturing a semiconductor chip are so stacked that the semiconductor chips are electrically coupled to each other via the respective through-electrodes, to thereby form a semiconductor device.

In addition, a semiconductor chip according to the invention of Patent Document 5 can be manufactured by the above-described manufacturing method. In this semiconductor chip, a through-electrode is provided in a through-hole arising from communicating of a first trench with a second trench. The first trench is formed by anisotropic etching from one face of a semiconductor substrate. The second trench is formed by anisotropic etching from the face opposite to the one face. Moreover, a semiconductor device according to the invention of Patent Document 5 is constructed through stacking of such semiconductor chips.

FIGS. 23C(a) to (h) are diagrams for explaining a method for manufacturing a semiconductor chip according to the first embodiment of the invention of Patent Document 5, and correspond to FIG. 2 in Patent Document 5.

Initially, as shown in FIG. 23C(a), a silicon substrate 401 is prepared and a semiconductor element (not shown) and an interconnect layer (not shown) are formed on the upper face of the substrate. Subsequently, a first insulating film 403 is formed to cover the entire upper face of the silicon substrate 401.

Referring next to FIG. 23C(b), patterning of the first insulating film 403 is carried out to form a mask aperture 403a in the first insulating film 403. This exposes a part of the upper face of the silicon substrate 401.

Subsequently, as shown in FIG. 23C(c), the silicon substrate 401 is etched from the upper-face side with use of the first insulating film 403 as the mask, so that a first trench 407a having a depth equal to about half the thickness of the silicon substrate 401 is formed by using the Bosch process.

Referring next to FIG. 23C(d), a second insulating film 405 to serve as a mask is formed on the entire back face of the silicon substrate 401. For example, this second insulating film may be composed of the same material as that of the first insulating film 403 and may be formed to have the same film thickness by using the same method as that for forming the first insulating film 403.

Subsequently, as shown in FIG. 23C(e), a mask aperture 405a is formed in the second insulating film 405. The size of the mask aperture 405a is substantially the same as that of the mask aperture 403a on the upper-face side. The mask aperture 405a is so positioned that the projection of the mask aperture 405a in the thickness direction of the silicon substrate 401 corresponds with the mask aperture 403a.

Subsequently, as shown in FIG. 23C(f), based on e.g. the Bosch process, the silicon substrate 401 is etched from the back-face side with use of the second insulating film 405 as the mask. Due to this etching, a second trench 407b in communication with the bottom of the first trench 407a is formed, so that a through-hole 408 formed of the first and second trenches 407a and 407b is formed. After the formation of the through-hole 408, a third insulating film (not shown) for electrically insulating the silicon substrate 401 from a through-electrode 402 is formed on the inner wall of the through-hole 408.

Subsequently, as shown in FIG. 23C(g), a conductive member 410z composed of a conductive material such as a metal is formed by using plating, sputtering, CVD, or the like. The conductive member 410z is so formed that the through-hole 408 is filled with the conductive member 410z and the entire surfaces of the first and second insulating films 403 and 405 are covered by the conductive member 410z. The conductive material provided in the through-hole 408 in this manner serves as the through-electrode 402.

Subsequently, as shown in FIG. 23C(h), patterning of the conductive member 410z formed on the first and second insulating films 403 and 405 is carried out. This forms protruding electrodes 404a and 404b that protrude from the insulating films 403 and 405, respectively, so that the conductive member 410 formed of the through-electrode 402 and the protruding electrodes 404a and 404b is formed.

Through the above-described series of steps, a semiconductor chip 420 is completed.

A semiconductor device is manufactured by stacking the thus manufactured semiconductor chips 420 in such a way that the chips are electrically coupled to each other via an anisotropic conductive film.

The first and second insulating films 403 and 405 are used not only as an insulating film but also as a mask for etching as described above. Therefore, the insulating films 403 and 405 need to be composed of a material having some degree of resistance to etching. In particular, the thickness of the insulating films 403 and 405 needs to be such that the insulating films 403 and 405 are not completely removed in etching before completion of formation of the trenches 407a and 407b.

The trenches 407a and 407b are not limited to ones having subsequently the same inside diameter, but the inside diameters of the first and second trenches 407a and 407b may be different from each other. In the case of forming the trenches having different inside diameters, the sizes of the mask apertures 403a and 405a formed in the insulating films 403 and 405, respectively, are changed to thereby vary the internal diameters of the trenches 407a and 407b.

The outline of the substrate-penetrating part in through-electrode structures in the above-described related arts is as follows.

FIGS. 24A and 24B are sectional views for explaining a through-electrode structure in the related arts. FIG. 24A is a sectional view along a plane perpendicular to the center axis of a through-hole having a circular shape. FIG. 24B is a sectional view along a plane including the center axis of the through-hole having a circular shape.

As shown in FIG. 24, the through-electrode structure includes an insulating layer (e.g., SiO₂) 41 formed on the inner wall of a through-hole 40 formed in a silicon substrate 30, a barrier layer (anti-diffusion layer, e.g., Ti or TiN) 42 formed inside the insulating layer 41, and a conductive layer (e.g., Cu, W, or poly-Si) 43 formed inside the barrier layer 42. The conductive layer 43 formed in one through-hole 40 serves as a single signal transmission path.

An SiP that includes plural chips connected to each other via through-electrodes can offer enhanced speed of signal transmission between the chips. However, forming of a through-electrode in a chip involves the need to form a through-hole that penetrates the chip from the active surface (face on which elements and interconnect circuits coupled thereto are formed) to the opposite back face. In the through-hole part, elements and interconnect circuits coupled thereto cannot be disposed. Therefore, because there is a need to form through-holes so as not to interfere with the arrangement of elements and interconnect circuits, an increase in the number of through-holes for enhancement in the speed of signal transmission between chips leads to problems of lowering of design flexibility and a chip area increase. The chip area increase reduces the theoretical yield of chips that can be manufactured from one wafer, which problematically results in an increase in costs of semiconductor chips.

The chip area increase can be suppressed by decreasing the diameter of through-holes. However, in the case of forming a 5 μmφ through-hole in a wafer substrate with a thickness of 0.1 mm to 0.15 mm for example, the aspect ratio of the through-hole ((depth of the through-hole)/(diameter of the through-hole)) is 20 to 30. Formation of such a high-aspect-ratio through-hole requires advanced etching technique and electrode-burying technique, and a production technique that can realize at low costs a semiconductor chip having a large number of micro through-holes has not been established yet as a general technique. The aspect ratio of a through-hole that can be realized at a practical level by a general production technique at low costs is about 2 to 3. Therefore, as the diameter of a through-hole is decreased, the depth of a through-hole that can be formed at a practical level also decreases. Accordingly, a chip needs to be manufactured with use of a thin wafer. Alternatively, a through-hole needs to be formed in the following manner: a recess having a small diameter is formed from one face of a wafer, and then the wafer is thinned by polishing the wafer from the other face until the polished surface reaches the bottom of the recess. This increases the difficulty of manufacturing step and assembling step for chips, which problematically increases technical development costs and processing costs.

Moreover, through-holes need to be arranged at a high density for suppression of chip size increase, which forces shortening of the distance between adjacent through-holes. This problematically leads to large crosstalk noise.

### SUMMARY OF THE INVENTION

There is a need for the present invention to provide a semiconductor device that has plural through-interconnects inside each through-hole and hence allows signal transmission without an increase in the number of through-holes even when a very large number of through-interconnects are required for signal transmission via through-interconnects that are formed inside through-holes formed in a substrate and penetrate the substrate from the front face to the back face thereof. Furthermore, there is another need for the invention to provide a method for manufacturing the semiconductor device.

According to an embodiment of the present invention, there is provided a semiconductor device in which a semiconductor chip is mounted over a substrate. The device includes a plurality of through-interconnects configured to be formed inside each of through-holes that penetrate the substrate and be led from the semiconductor chip to the face of the substrate on the opposite side of the semiconductor chip.

According to another embodiment of the present invention, there is provided a method for manufacturing a semiconductor device. The method includes the steps of forming through-holes that penetrate a substrate, and forming a plurality of through-interconnects that penetrate the substrate inside each of the through-holes with intermediary of an electrically insulating layer between the through-interconnects.

According to the embodiments of the present invention, plural through-interconnects that penetrate a substrate from the front face to the back face thereof are formed inside each of through-holes formed in the substrate. Therefore, even when a very large number of through-interconnects are required, the formation of plural through-interconnects inside each through-hole allows signal transmission without an increase in the number of through-holes. This feature can provide a semiconductor device with a smaller area and a method for manufacturing the same.

### BRIEF DESCRIPTION OF THE DRAWINGS

FIGS. 1A, 1B and 1C are a plan view, sectional view along the line Z-Z, and enlarged view around the part A, respectively, for explaining the structure of a semiconductor device formed by stacking chips having through-interconnects according to an embodiment of the present invention;

FIGS. 2A and 2B are sectional views for explaining a through-interconnect structure in a semiconductor chip according to an embodiment of the invention;

FIG. 3 is a flowchart for explaining a method for manufacturing through-interconnects in a semiconductor chip according to an embodiment of the invention;

FIGS. 4A to 4D are diagrams (first group) for explaining a manufacturing method A for through-interconnects in a semiconductor chip according to an embodiment of the invention;

FIGS. 5A to 5D are diagrams (second group) for explaining the manufacturing method A for through-interconnects in a semiconductor chip according to an embodiment of the invention;

FIGS. 6A to 6D are diagrams (third group) for explaining the manufacturing method A for through-interconnects in a semiconductor chip according to an embodiment of the invention;

FIGS. 7A to 7D are diagrams (fourth group) for explaining the manufacturing method A for through-interconnects in a semiconductor chip according to an embodiment of the invention;

FIGS. 8A to 8D are diagrams (first group) for explaining a manufacturing method B for through-interconnects in a semiconductor chip according to an embodiment of the invention;

FIGS. 9A to 9D are diagrams (second group) for explaining the manufacturing method B for through-interconnects in a semiconductor chip according to an embodiment of the invention;

FIGS. 10A to 10D are diagrams (third group) for explaining the manufacturing method B for through-interconnects in a semiconductor chip according to an embodiment of the invention;

FIG. 11A to 11D are diagrams for explaining a manufacturing method C for through-interconnects in a semiconductor chip according to an embodiment of the invention;

FIGS. 12A and 12B are a plan view and sectional view, respectively, for explaining a size example relating to through-interconnects in a semiconductor chip according to an embodiment of the invention;

FIGS. 13A, 13B and 13C are a plan view, sectional view along the line Z-Z, and enlarged view around the part C, respectively, for explaining the structure of another example of a semiconductor device formed by stacking chips having through-interconnects according to an embodiment of the invention;

FIGS. 14A, 14B and 14C are a plan view, sectional view along the line Z-Z, and enlarged view around the part B, respectively, for explaining the structure of another example of a semiconductor device formed by stacking chips having through-interconnects according to an embodiment of the invention;

FIGS. 15A, 15B and 15C are a plan view, sectional view along the line Z-Z, and enlarged view around the part D, respectively, for explaining the structure of another example of a semiconductor device formed by stacking chips having through-interconnects according to an embodiment of the invention;

FIGS. 16A and 16B are a plan view and sectional view along the line Z-Z, respectively, for explaining the structure of another example of a semiconductor device formed by stacking chips having through-interconnects according to an embodiment of the invention;

FIGS. 17A and 17B are a plan view and sectional view along the line Z-Z, respectively, for explaining the structure of another example of a semiconductor device formed by stacking chips having through-interconnects according to an embodiment of the invention;

FIGS. 18A to 18C are sectional views for explaining the structures of (first) modifications of through-interconnects according to an embodiment of the invention;

FIGS. 19A to 19C are sectional views for explaining the structures of (second) modifications of through-interconnects according to an embodiment of the invention;

FIGS. 20A and 20B are sectional views for explaining the structures of (third) modifications of through-interconnects according to an embodiment of the invention;

FIGS. 21A to 21C are diagrams for explaining through-electrodes in a related art;

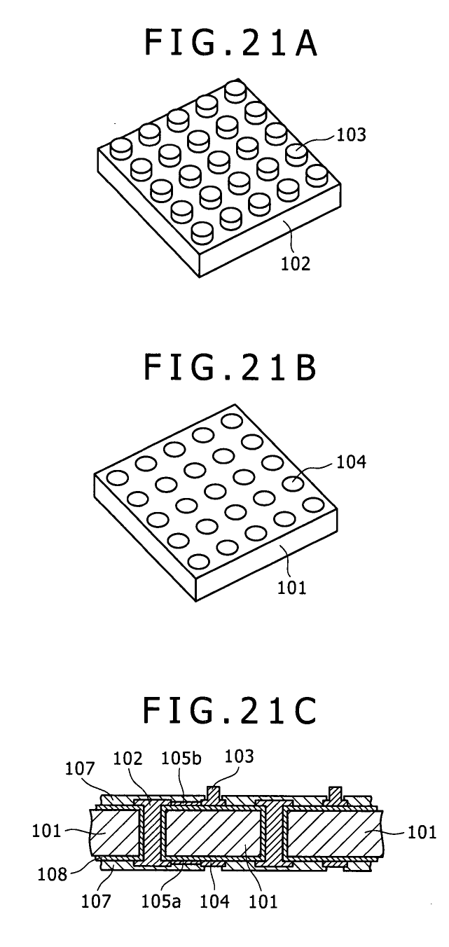

FIGS. 22A and 22B are diagrams for explaining the through-electrodes in the related art;

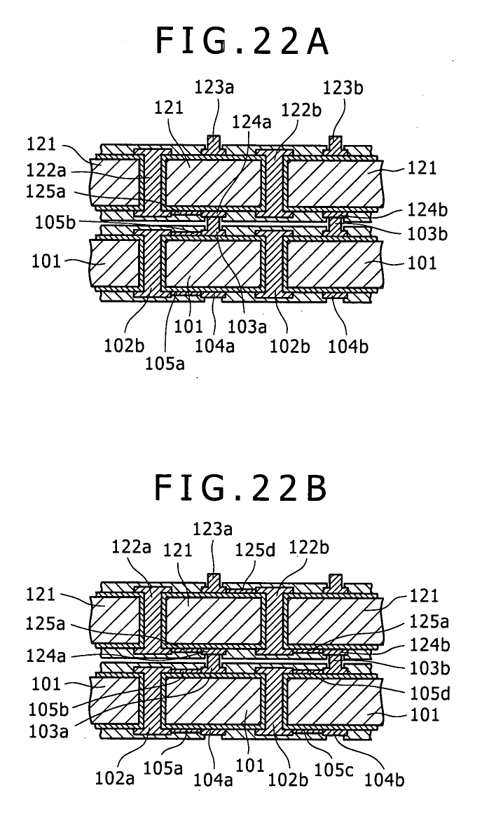

FIGS. 23A to 23C are diagrams for explaining through-electrodes in related arts; and

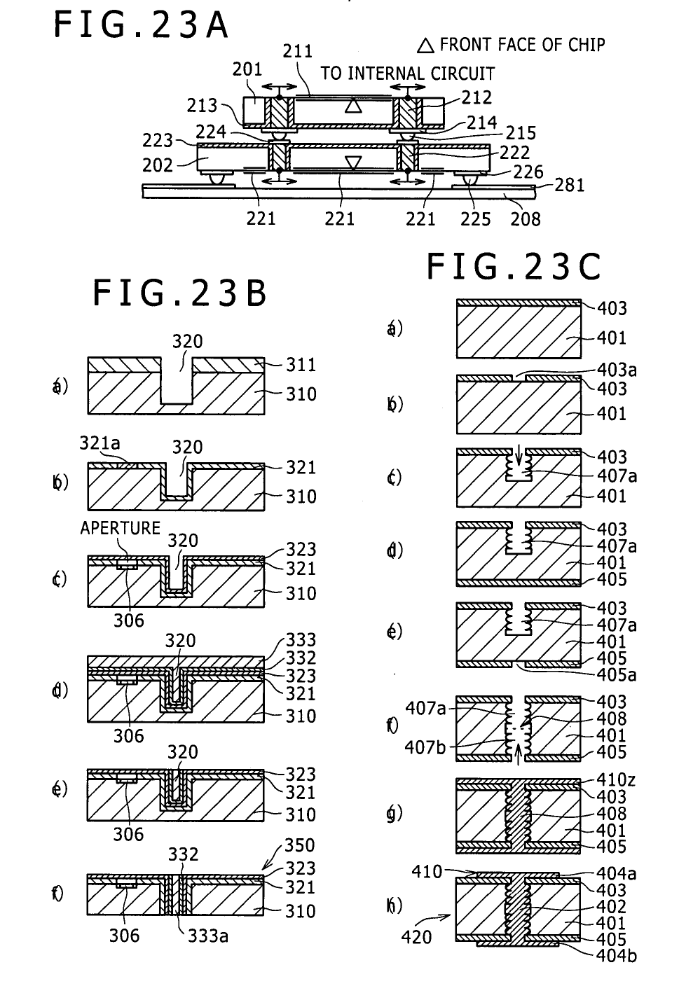

FIGS. 24A and 24B are diagrams for explaining a through-electrode in the related arts.

### DETAILED DESCRIPTION OF THE PREFERRED EMBODIMENT

In a semiconductor device according to an embodiment of the present invention, it is preferable to form in a through-hole an insulating layer for electrically insulating plural through-interconnects from each other. If plural through-interconnects are electrically insulated from each other, the through-interconnects can be used as interconnect lines that transmit signals independently of each other. Furthermore, it is preferable that the plural through-interconnects be concentric with each other. This allows formation of plural through-interconnects having a large sectional area.

In addition, it is preferable that the through-holes be formed in a peripheral region or an inside region of the peripheral region of the substrate. Because plural through-interconnects are formed in one through-hole, there is no need to form through-holes at a high density, which can suppress a substrate size increase. Even when through-holes are formed in an element-formation region on a substrate, design flexibility is not very deteriorated. When through-holes are formed in a peripheral region of a substrate, the through-holes can be formed in a region in which electrode pads designed on the premise of existing wire bonding are formed. Therefore, a large design change is not required but it is sufficient to add to design for fabrication of an existing substrate, design for opening a necessary number of through-holes in the region in which the electrodes pads for wire bonding are formed and forming plural through-interconnects inside these through-holes.

Moreover, it is preferable that the substrate be a semiconductor substrate stacked on a semiconductor chip. If the substrate is a semiconductor substrate formed by a semiconductor process, a semiconductor device can be manufactured by a wafer-level process, which allows low-cost manufacturing.

Furthermore, it is preferable that a plurality of these semiconductor substrates be stacked and the through-holes and the through-interconnects be formed in each semiconductor substrate. This can realize a semiconductor device that can implement more complex functions at high speed.

In a method for manufacturing a semiconductor device according to an embodiment of the present invention, it is preferable that in the step of forming plural through-interconnects, the through-interconnects be formed on the inner circumferential surface of a through-hole by through-hole plating. Because the through-hole plating is a technically-established stable production scheme, the through-interconnects can be formed stably at low costs.

Embodiments of the present invention will be described in detail below with reference to the accompanying drawings.

An embodiment of the invention relates to a semiconductor device in which a semiconductor chip is mounted on a substrate. This semiconductor device has a structure in which plural interconnects coupled to the semiconductor chip are formed inside a through-hole penetrating the substrate, and these through-interconnects are led to the opposite face of the substrate. As this substrate, any of the following substrates is used: an insulating interposer substrate formed of an insulator; a semiconductor interposer substrate formed of a semiconductor such as silicon; and a substrate serving as a semiconductor chip on which various active elements and passive elements, according to need, are formed.

If the substrate is an insulating or semiconductor interposer substrate, on this interposer substrate, various passive elements are incorporated or mounted, and various electronic components such as semiconductor chips and an SiP on which various active elements are formed are mounted. Sensor elements are also mounted according to need. The interposer substrate on which various electronic components are mounted is used as a module for an electronic apparatus. Electric connection between the module and the electronic apparatus is implemented by plural through-interconnects formed in each of plural through-holes formed in the interposer substrate.

If the substrate is a component serving as a semiconductor chip, a stacked semiconductor device in which plural semiconductor chips are stacked is obtained, and signals are transmitted between the stacked semiconductor chips via the through-interconnects at high speed. Embodiments of the present invention will be described below by taking as examples such semiconductor devices.

The semiconductor chip used in the stacked semiconductor device has, in each through-hole, two or more conductive layers electrically insulated from each other as through-interconnects. The through-hole penetrates the substrate serving as the semiconductor chip from the functional surface that is formed on the front-face side of the substrate and includes active elements to the back face of the substrate. The through-hole is formed by wet or dry etching.

For example, inside one through-hole, insulating layers and conductive layers are deposited alternately along the radius direction of the through-hole for formation of through-interconnects in the through-hole, so that two or more conductive layers electrically insulated from each other are formed as the through-interconnects, and the respective conductive layers are used as signal transmission interconnect lines independent of each other. The term “signal transmission interconnect lines” encompass also power supply lines and ground signal supply lines. Hereinafter, the surface on which elements and interconnect circuits coupled thereto are formed is referred to as an active surface or the front-face side of a semiconductor substrate, while the side opposite to the front-face side is referred to as the back-face side.

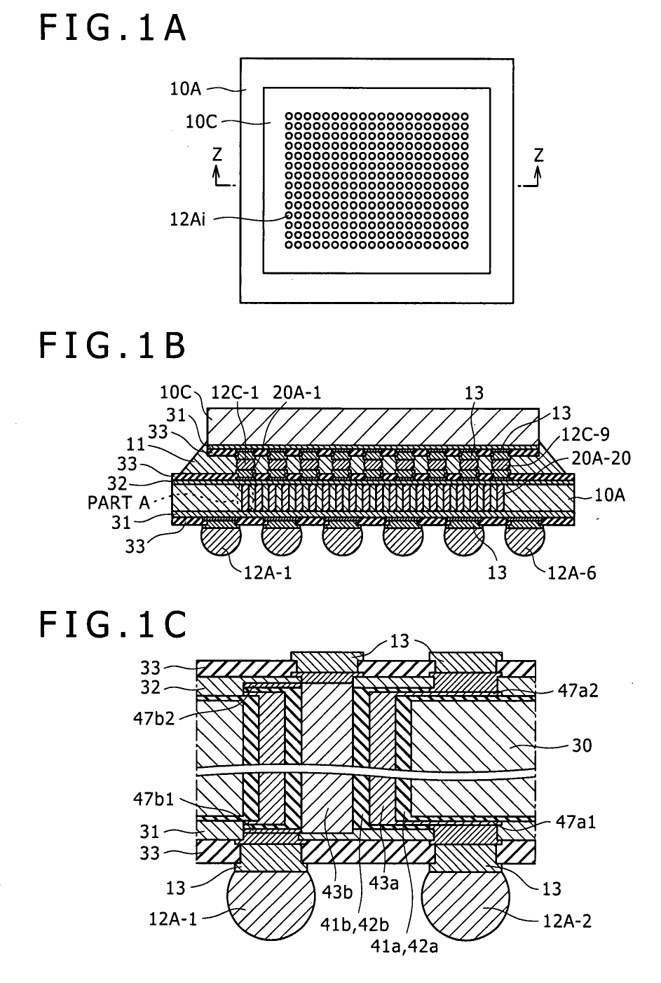

FIGS. 1A to 1C are diagrams for explaining the structure of a semiconductor device formed by stacking chips having through-interconnects according to an embodiment of the invention. FIG. 1A is a plan view. FIG. 1B is a sectional view along the line Z-Z. FIG. 1C is an enlarged view around the part A (sectional view of interconnects coupled to the leftmost through-interconnect 20A-1).

In a semiconductor chip 10A of the present embodiment, through-interconnects 20Ai (i=1, 2, . . . , I (I is an integer number)) are formed inside through-holes that penetrate from an element and interconnect circuit layer 31 formed on the front-face side of a silicon (Si) substrate 30 of the chip to a redistribution layer 32 and an insulating layer 33 formed on the back-face side of the Si substrate. In FIGS. 1A and 1B, through-interconnects arranged in a matrix of 14 rows by 20 columns are shown, and the through-interconnects 20A-1 to 20A-20 along the line Z-Z are shown, respectively.

As shown in FIG. 1C, the through-interconnect 20A-1 is formed of a first insulating layer 41a, a first barrier layer 42a, a first conductive layer 43a, a second insulating layer 41b, a second barrier layer 42b, and a second conductive layer 43b that are formed inside a through-hole.

The first conductive layer 43a is electrically coupled via an interconnect 47a1 formed on the front-face side of the Si substrate 30 to an electrode pad (on which a barrier metal (under-bump metal) 13 having thereon a bump 12A-2 is formed). Furthermore, the first conductive layer 43a is electrically coupled via an interconnect 47a2 formed on the back-face side of the Si substrate 30 to an electrode pad (on which the barrier metal 13 is formed).

The second conductive layer 43b is electrically coupled via an interconnect 47b1 formed on the front-face side of the Si substrate 30 to an electrode pad (on which the barrier metal 13 having thereon a bump 12A-1 is formed). Furthermore, the second conductive layer 43b is electrically coupled to the barrier metal 13 formed on an electrode pad on the back-face side of the Si substrate 30. The second conductive layer 43b may be electrically coupled to an electrode pad (on which the barrier metal 13 is formed) provided on an interconnect 47b2 formed on the back-face side of the Si substrate 30. Although FIG. 1B shows only bumps 12A-1 to 12A-6 along the line Z-Z, bumps 12Ak (k=1, 2, . . . , K (K is an integer number)) are formed on the entire semiconductor chip 10A.

The redistribution layer 32 includes the electrode pads and the interconnects 47a2 and 47b2 coupled to the first and second conductive layers 43a and 43b, respectively. The element and interconnect circuit layer 31 includes the electrode pads and the interconnects 47a1 and 47b1 coupled to the first and second conductive layers 43a and 43b, respectively.

As shown in FIGS. 1A and 1B, the semiconductor device of the present embodiment is an SiP formed by stacking the semiconductor chip 10A and a semiconductor chip 10C. The semiconductor chips 10A and 10C are electrically connected to each other via the through-interconnects 20Ai and bumps 12Cn (n=1, 2, . . . , N (N is an integer number), FIG. 1B shows only bumps 12C-1 to 12C-9 along the line Z-Z). An underfill material 11 serves to protect the connection part and combine two semiconductor chips 10A and 10C. It should be obvious that an SiP in which three or more semiconductor chips are stacked and electrically connected to each other via through-interconnects is also possible as a semiconductor device as described later.

Although FIG. 1 shows the example in which through-holes are arranged in a matrix of 14 rows by 20 columns and through-interconnects are formed therein, an actual device has a structure in which two or more semiconductor chips are connected via through-interconnects formed in a very large number of through-holes, such as several thousands of through-holes.

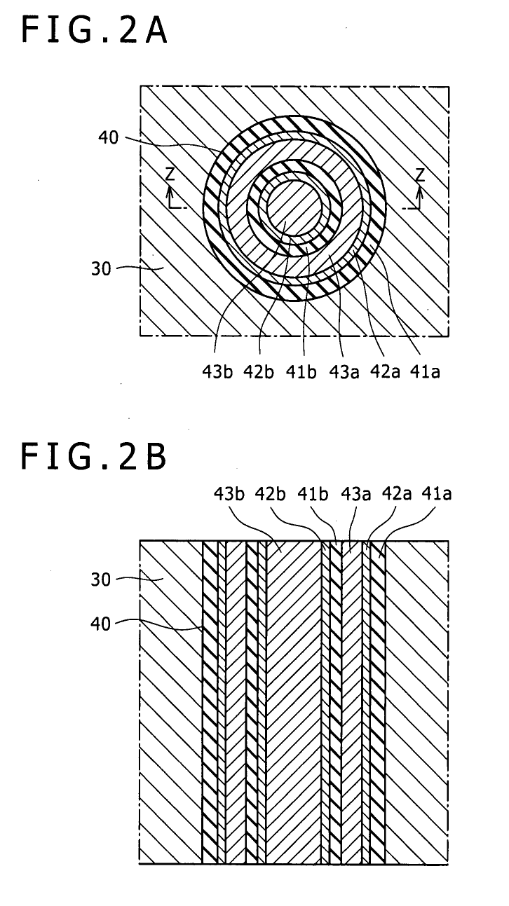

FIGS. 2A and 2B are sectional views for explaining the structure of a through-interconnect in a semiconductor chip according to an embodiment of the present invention. FIG. 2A is a sectional view along a plane perpendicular to the center axis of a circular through-hole. FIG. 2B is a sectional view along a plane including the center axis of the circular through-hole.

As shown in FIGS. 2A and 2B, the through-interconnect according to the present embodiment is formed of the first insulating layer 41a that has a hollow cylinder shape and is formed in tight contact with the inner wall of a through-hole 40 penetrating the Si substrate 30, the first barrier layer 42a that has a hollow cylinder shape and is formed in tight contact with the first insulating layer 41a, and the first conductive layer 43a formed in tight contact with the first barrier layer 42a. Furthermore, the through-interconnect is formed of the second insulating layer 41b that has a hollow cylinder shape and is formed in tight contact with the first conductive layer 43a, the second barrier layer 42b that has a hollow cylinder shape and is formed in tight contact with the second insulating layer 41b, and the second conductive layer 43b that has a cylinder shape and is formed in tight contact with the second barrier layer 42b.

In the example of FIG. 2, the through-hole 40 is completely filled with the respective layers. However, the second conductive layer 43b may be formed to have a hollow cylinder shape so that a part of the through-hole 40 may be hollow.

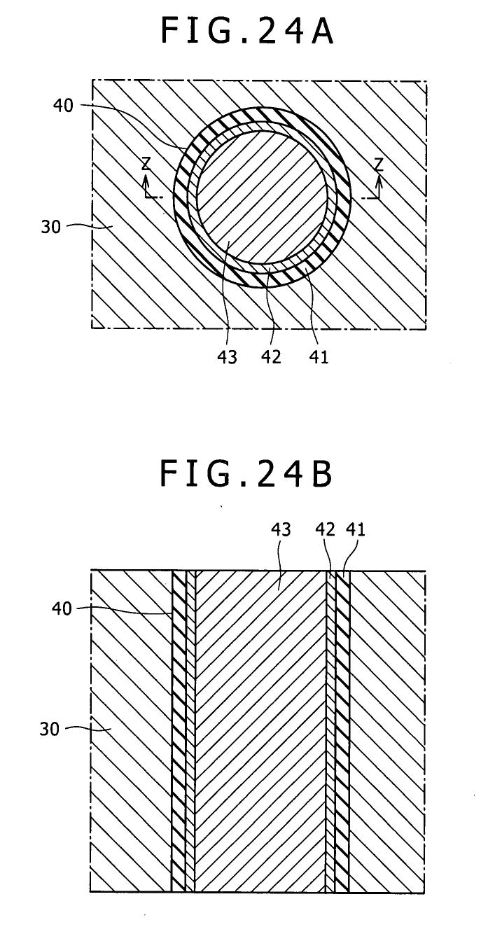

The through-interconnect of the present embodiment is greatly different from the through-electrode by the related art shown in FIG. 24, in that plural conductive layers are formed inside the through-hole 40 in a semiconductor substrate in such a manner as to be insulated from each other by an insulating layer. In the related art, only a single conductive layer is formed in one through-hole, and hence only a single signal transmission path can be ensured therein. In contrast, plural conducive layers are formed in one through-hole in the present embodiment. Therefore, the respective conductive layers can be used as interconnect lines (through-interconnects) through which different signals are transmitted, and thus plural signal transmission paths can be ensured in one through-hole.

Note that only components relating to a through-hole formed inside a semiconductor substrate are shown in FIGS. 24 and 2, and illustration is omitted regarding elements and interconnect circuits formed on the front-face and back-face sides of the semiconductor substrate, electrode pads coupled to the elements and the interconnect circuits, under-bump metals, bump electrodes, and so on.

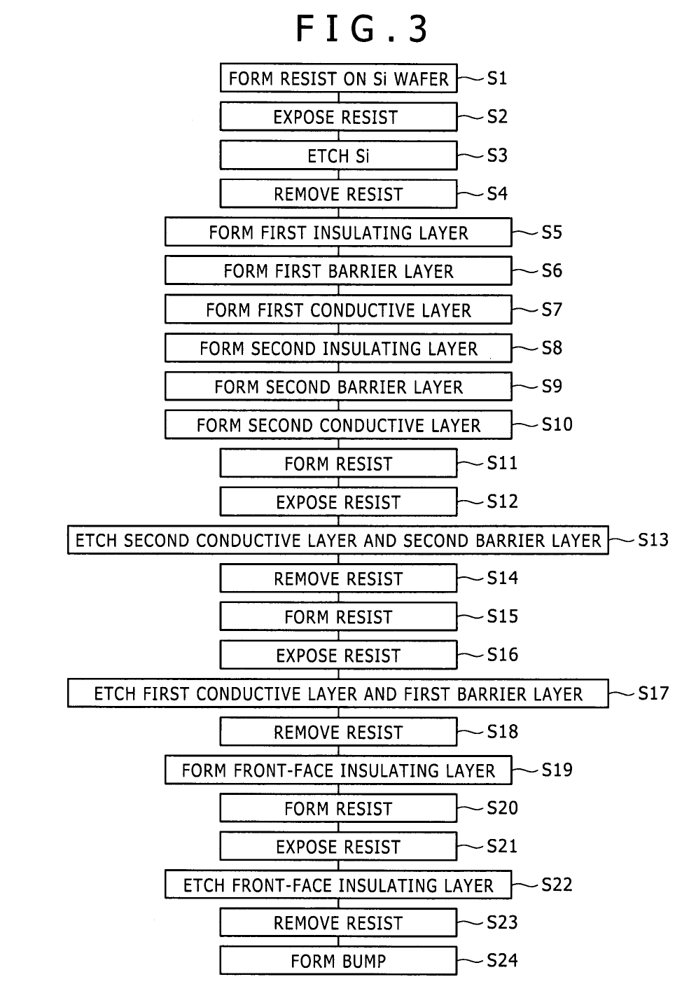

A description will be made below about a method for manufacturing through-interconnects in a semiconductor chip with reference to FIGS. 3 to 11, by taking as an example a structure in which two conductive layers are formed inside one through-hole as through-interconnects to serve as signal transmission interconnect lines. A wafer-scale process is employed as the manufacturing process. For simplified description, FIGS. 3 to 11 show the structure of through-interconnects formed inside one through-hole.

FIG. 3 is a flowchart for explaining the method for manufacturing through-interconnects in a semiconductor chip according to an embodiment of the present invention.

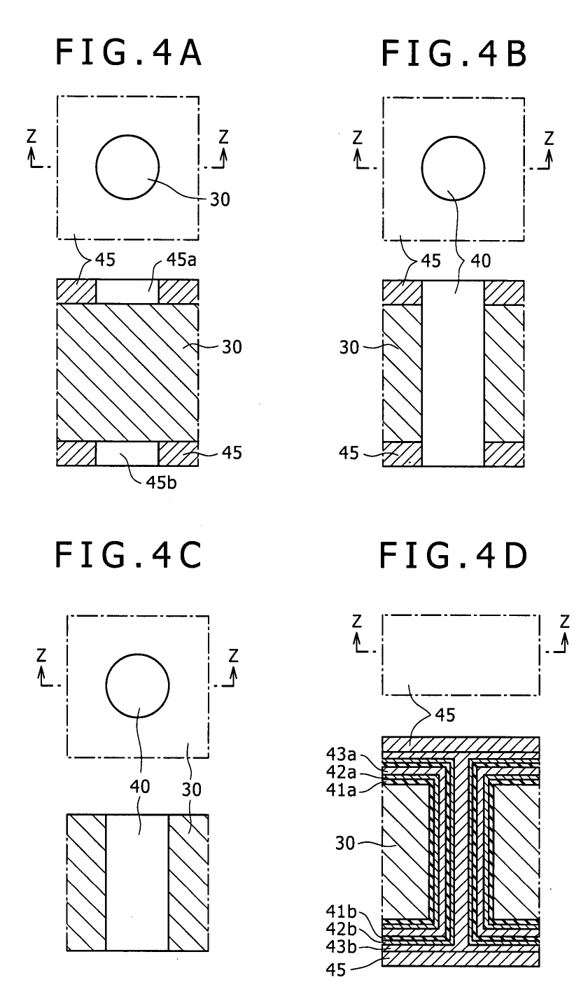

FIGS. 4 to 7 are diagrams for explaining a manufacturing method A for through-interconnects in a semiconductor chip according to an embodiment of the present invention. The upper drawings and the lower drawings of FIGS. 4A to 7D are plan views and sectional views along the line Z-Z, respectively.

For formation of a through-hole in a semiconductor substrate, any of known various methods can be used. In formation of plural conductive layers to serve as signal transmission interconnect lines (through-interconnects) inside the formed through-hole, manufacturing steps are repeated in accordance with a desired procedure as described below, which allows formation of a through-interconnect structure having the intended number of conductive layers. The manufacturing steps include formation of an insulating layer, formation of a barrier layer, formation of a conductive layer, formation of a resist, exposure of a resist, and etching.

In the manufacturing method shown in FIGS. 4 to 7, the through-hole is formed by etching from one face of a wafer. This manufacturing method is applied to formation of a through-hole having an aperture diameter of 10 μm to 80 μm with use of a wafer having a thickness of 30 μm to 200 μm.

The respective steps S1 to S24 shown in FIG. 3 will be sequentially described below with reference to FIGS. 4 to 7.

S1: Step of Forming a Resist on a Silicon (Si) Wafer

To form the through-hole 40 penetrating from the front face to the back face of the Si wafer (substrate) 30, a resist is applied on the whole of the front and back faces to thereby form resist layers 45.

S2: Step of Exposing the Resist

Referring to FIG. 4A, exposure is carried out for a part of the resist layers 45 on the front and back faces, at the positions between which the through-hole 40 of the Si substrate 30 is to be formed, so that resist apertures 45a and 45b are formed.

S3: Step of Etching Si

As shown in FIG. 4B, the through-hole 40 penetrating from the front face to the back face of the Si substrate 30 is formed by using dry etching. As the dry etching, a general technique employing a fluorine gas, chlorine gas, or the like can be used. It is preferable to employ inductively coupled plasma reactive ion etching (ICP-RIE), which allows high-speed deep etching.

S4: Step of Removing the Resist

As shown in FIG. 4C, the resist layers 45 on the front and back faces of the Si substrate 30 are removed.

Subsequently, as shown in FIG. 4D, the respective layers are sequentially formed inside the through-hole 40 in the order of the following steps S5 to S11.

S5: Step of Forming a First Insulating Layer

Initially, the first insulating layer 41a is formed on the inner wall of the through-hole 40 and the front and back faces of the Si substrate 30.

S6: Step of Forming a First Barrier Layer

The first barrier layer 42a is formed on the first insulating layer 41a on the inner wall of the through-hole 40 and the front and back faces.

S7: Step of Forming a First Conductive Layer

The first conductive layer 43a is formed on the first barrier layer 42a over the inner wall of the through-hole 40 and the front and back faces. Through the steps S5 to S7, the layers constructing a first through-interconnect are formed.

S8: Step of Forming a Second Insulating Layer

Subsequently, the second insulating layer 41b is formed on the first conductive layer 43a over the inner wall of the through-hole 40 and the front and back faces.

S9: Step of Forming a Second Barrier Layer

The second barrier layer 42b is formed on the second insulating layer 41b over the inner wall of the through-hole 40 and the front and back faces.

S10: Step of Forming a Second Conductive Layer

The second conductive layer 43b is formed on the second barrier layer 42b over the inner wall of the through-hole 40 and the front and back faces, so that the through-hole 40 is filled with the second conductive layer 43b and the whole of the front and back faces is covered by the second conductive layer 43b. Through the steps S8 to S10, the layers constructing a second through-interconnect are formed.

S11: Step of Forming a Resist

A resist is applied on the entire surfaces of the second conductive layer 43b on the front and back faces to thereby form the resist layers 45.

It is preferable for the first and second insulating layers to include no pinhole and have favorable electric insulating characteristics. Used as these layers is e.g. a thermally-oxidized layer formed by thermal oxidation treatment or a plasma oxidized layer formed by plasma CVD. The material of these layers is SiO₂ or Si₃N₄, and the thickness thereof is e.g. 0.1 μm to 0.3 μm.

The first and second barrier layers are to prevent diffusion of metals of the first and second conductive layers. These layers are composed of e.g. TiN and have a thickness of e.g. 0.05 μm to 0.1 μm.

The first and second conductive layers are formed as copper (Cu) layers by electrolytic plating with use of the metal layers formed as the first and second barrier layers as the electrodes. The thickness of these conductive layers is e.g. 1 μm to 10 μm.

S12: Step of Exposing the Resist

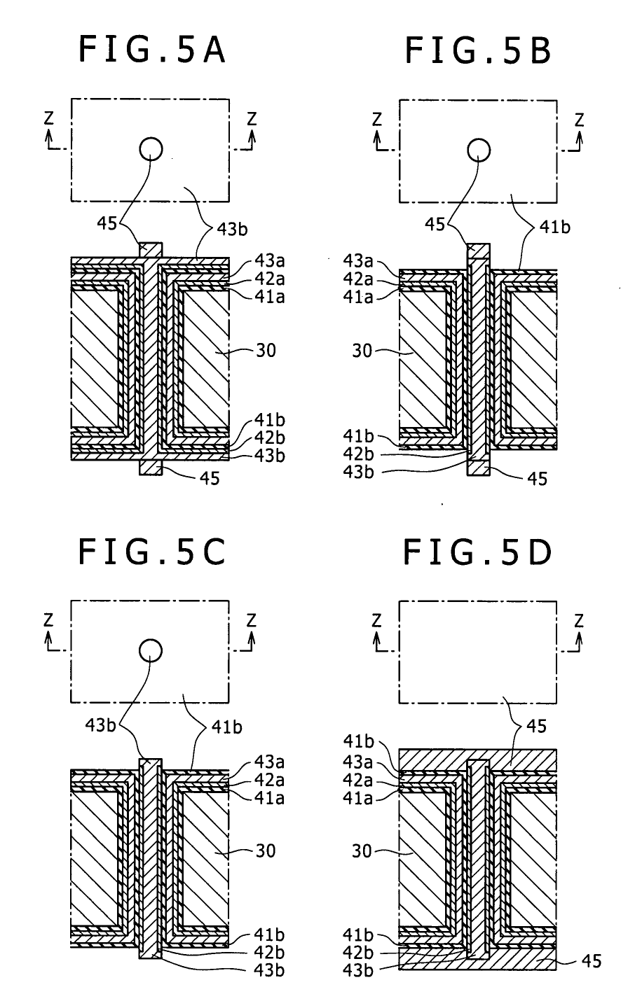

Referring to FIG. 5A, the resist layers 45 on the front and back faces are exposed with use of a mask. By this exposure, the second conductive layer 43b is exposed at the front and back faces in such a way that only the resist layers 45 over and below the second conductive layer 43b inside the through-hole are left.

S13: Step of Etching the Second Conductive Layer and the Second Barrier Layer.

As shown in FIG. 5B, the second conductive layer 43b exposed at the front and back faces is removed by etching, and then the second barrier layer 42b is also etch-removed, so that the second insulating layer 41b is exposed.

S14: Step of Removing the Resist

As shown in FIG. 5C, the resist layers 45 left on the front and back faces are removed to thereby expose the second conductive layer 43b.

S15: Step of Forming a Resist

As shown in FIG. 5D, a resist is applied on the entire surfaces of the second conductive layer 43b and the second insulating layer 41b on the front and back faces, to thereby form the resist layers 45 on the front and back faces.

S16: Step of Exposing the Resist

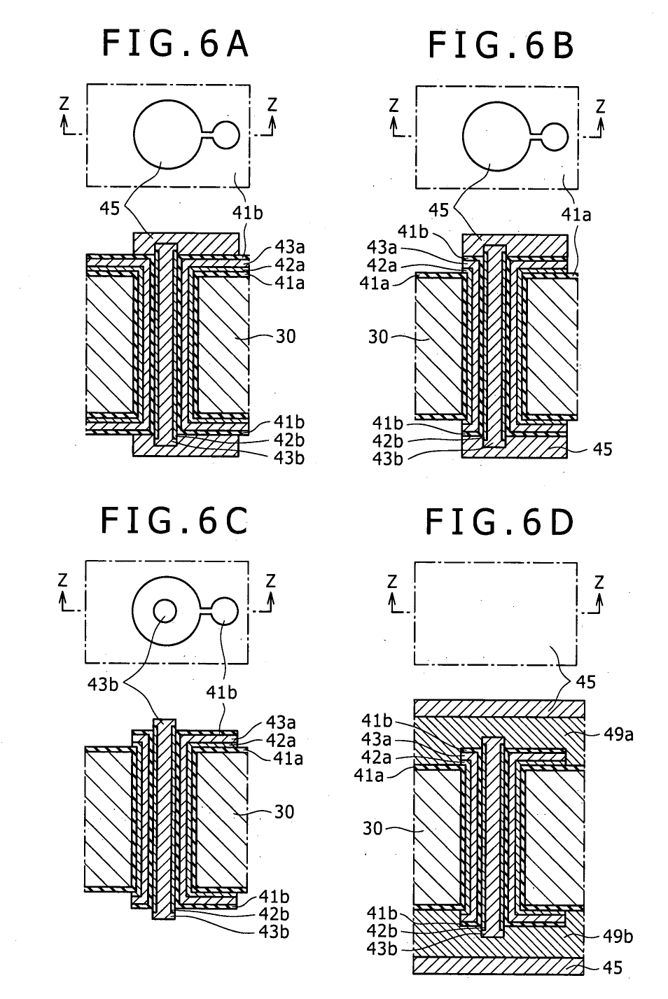

Referring to FIG. 6A, the resist layers 45 on the front and back faces, other than the layers 45 in the vicinity of the through-hole 40, are exposed so as to be removed with use of a mask for forming electrode terminals, so that the second insulating layer 41b is exposed.

S17: Step of Etching the First Conductive Layer and the First Barrier Layer.

As shown in FIG. 6B, the second insulating layer 41b exposed at the front and back faces is removed by etching. Subsequently, the first conductive layer 43a and the first barrier layer 42a, which are sequentially exposed, are also etch-removed, so that the first insulating layer 41a is exposed.

S18: Step of Removing the Resist

As shown in FIG. 6C, the resist layers 45 on the front and back faces are removed to thereby expose the second conductive layer 43b and the second insulating layer 41b at the front and back faces.

S19: Step of Forming Front-Face and Back-Face Insulating Layers

As shown in FIG. 6D, a front-face insulating layer 49a is formed on the front face, and a back-face insulating layer 49b is formed on the back face.

S20: Step of Forming a Resist

As shown in FIG. 6D, a resist is applied on the entire surfaces of the insulating layers 49a and 49b formed on the front and back faces, to thereby form the resist layers 45.

S21: Step of Exposing the Resist

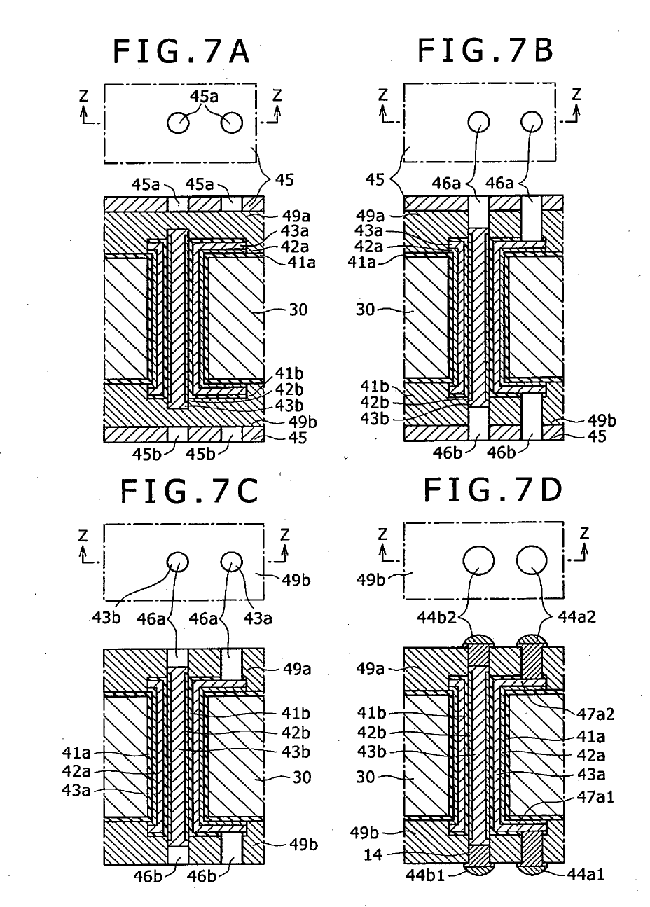

Referring to FIG. 7A, the resist layers 45 on the front and back faces are exposed with use of a mask, and thereby apertures 45a and 45b are formed on the front face and the back face, respectively, for formation of electrode terminals.

S22: Step of Etching the Front-Face and Back-Face Insulating Layers.

As shown in FIG. 7B, the front-face insulating layer 49a and the back-face insulating layer 49b are removed by etching to thereby form recesses 46a and 46b, so that the second conductive layer 43b and the first conductive layer 43a are exposed at the bottoms of the recesses 46a and 46b.

S23: Step of Removing the Resist

As shown in FIG. 7C, the resist layers 45 are removed to thereby expose the insulating layers 49a and 49b at the front and back faces.

S24: Step of Forming Bumps

As shown in FIG. 7D, pads and barrier metals (under-bump metals) 14 are formed in the recesses 46a and 46b on the front-face and back-face sides. Furthermore, bumps (or pads) 44a2 and 44b2, and bumps 44a1 and 44b1 are formed. As a result, the first conductive layer 43a in the through-hole 40 is electrically connected to the bump (or pad) 44a2 and the bump 44a1 via the front-face side interconnect 47a2 and the back-face side interconnect 47a1, respectively, which are connected to the first conductive layer 43a. In addition, the second conductive layer 43b in the through-hole 40 is electrically connected to the front-face side bump (or pad) 44b2 and the back-face side bump 44b1, respectively.

In the above-described manner, through-interconnects are formed by the respective layers formed on the front and back faces of the Si substrate 30 and inside the through-hole 40 penetrating the Si substrate 30.

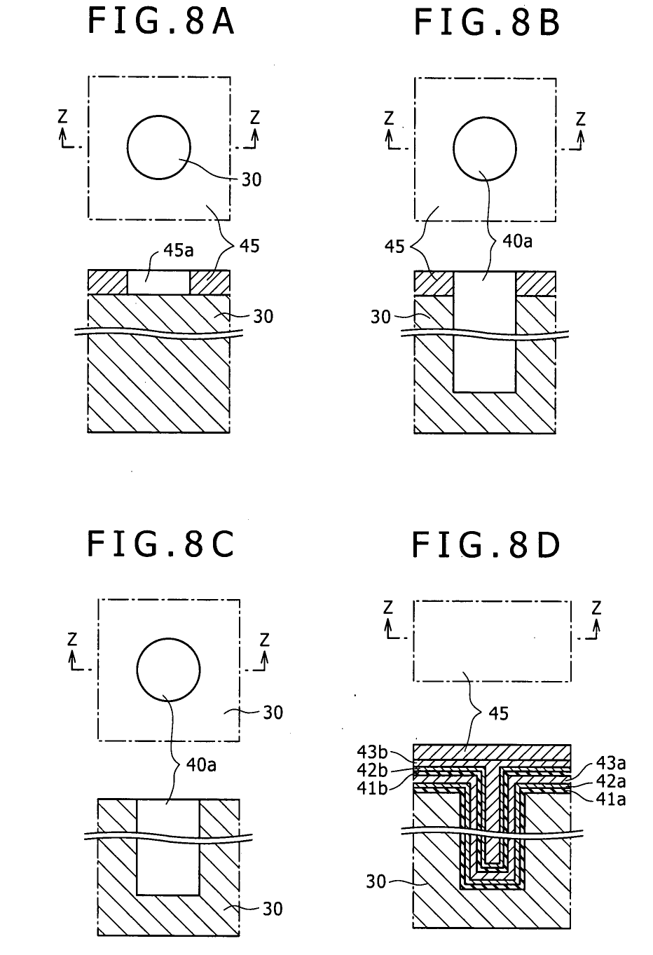

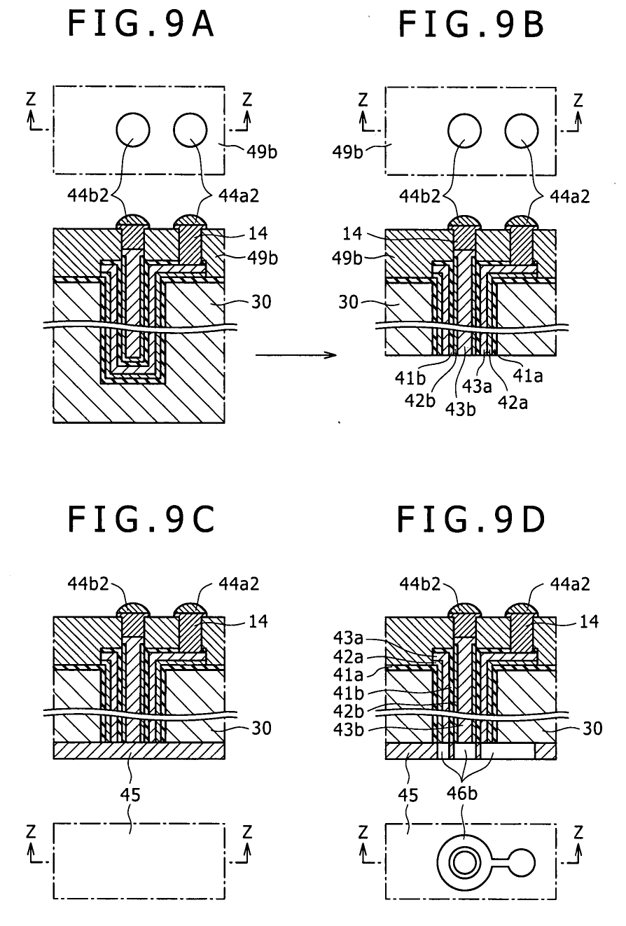

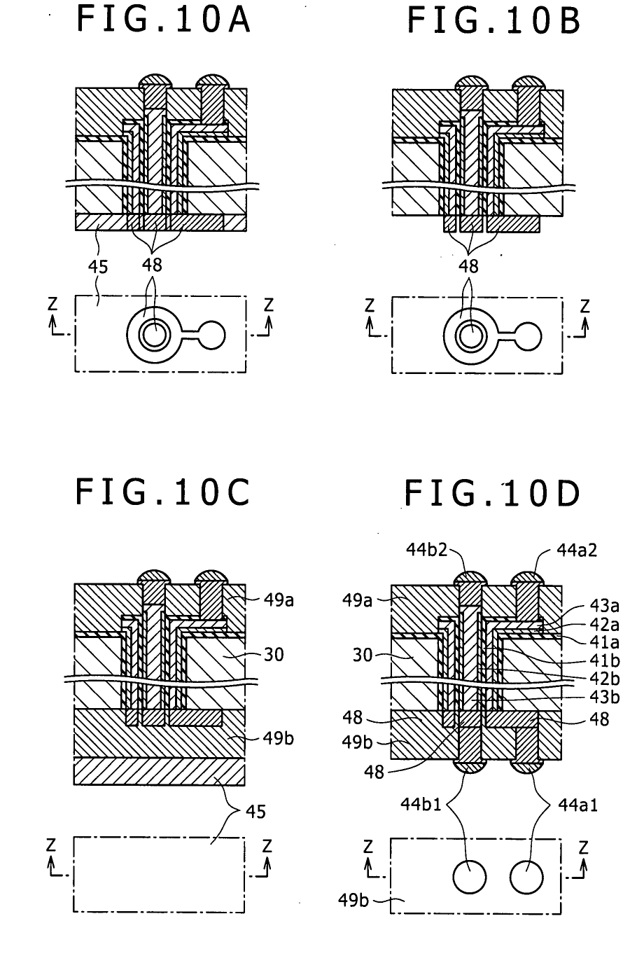

FIGS. 8 to 10 are diagrams for explaining a manufacturing method B for through-interconnects in a semiconductor chip according to an embodiment of the present invention. The upper drawings and the lower drawings of FIGS. 8A to 8D, 9A, and 9B are plan views and sectional views along the line Z-Z, respectively. The upper drawings and the lower drawings of FIGS. 9C, 9D, and 10A to 10D are sectional views along the line Z-Z and lower face views, respectively.

The manufacturing method B shown in FIGS. 8 to 10 is employed for the case where it is difficult to form a through-hole at a practical level by etching only from one face of a wafer. In this method B, etching is carried out from one face of a wafer to thereby form a recess, and then polishing is carried out from the other face of the wafer, to thereby form a through-hole opened from both the faces of the wafer (refer to Patent Document 4, Non-Patent Documents 1, 2, and 5). This manufacturing method is applied to formation of a through-hole having an aperture diameter of 10 μm to 80 μm with use of a wafer having a thickness of 300 μm to 1000 μm. In this method, the thickness of the finally obtained wafer is small.

In the manufacturing method A described with FIGS. 3 to 7, a through-hole penetrating a wafer (Si substrate 30) is formed as shown in FIG. 4B. In contrast, in the manufacturing method B, a recess 40a that does not penetrate a Si substrate 30 but has an aperture on the front-face side is formed as shown in FIGS. 8A and 8B. The above-described general dry etching or ICP-RIE can be applied to the formation of the recess.

Subsequently, as shown in FIGS. 8C and 8D, on the inner sidewall and the bottom of the recess 40a, a first insulating layer 41a, a first barrier layer 42a, a first conductive layer 43a, a second insulating layer 41b, a second barrier layer 42b, and a second conductive layer 43b are sequentially formed in that order, so that the inside of the recess 40a is filled with the second conductive layer 43b and the front face is covered by the second conductive layer 43b. Subsequently, a resist is applied on the entire surface of the second conductive layer 43b to thereby form a resist layer 45. Thereafter, in the same manner as that of the manufacturing method A, interconnects coupled to bumps (or pads) 44a2 and 44b2 are formed on the front-face side.

Subsequently, as shown in FIGS. 9A and 9B, the substrate 30 is polished from the back-face side until the plane indicated by the dashed line is exposed, so that the first insulating layer 41a, the first barrier layer 42a, the first conductive layer 43a, the second insulating layer 41b, the second barrier layer 42b, and the second conductive layer 43b are exposed at the back face. This polishing is carried out by CMP.

Thereafter, as shown in FIGS. 9C to 10D, interconnects coupled to the first and second conductive layers 43a and 43b, pads, barrier metals, bumps, and so on are formed on the back-face side.

Specifically, the resist layer 45 is formed on the entire back face (see FIG. 9C), and then the resist layer 45 is exposed with use of a mask to thereby form apertures 46b. This exposes the first conductive layer 43a and the part coupled thereto, and the second conductive layer 43b and the part coupled thereto in such a way that the first and second conductive layers 43a and 43b are isolated from each other (see FIG. 9D). Thereafter, a conductive layer 48 is formed inside the apertures 46b, and then the resist layer 45 is removed (see FIGS. 10A and 10B).

Subsequently, a back-face insulating layer 49b and the resist layer 45 are formed. Thereafter, in the same manner as that of the manufacturing method A, pads, barrier metals, bumps, and so on coupled via the conductive layer 48 to the first and second conductive layers are formed, so that the same through-interconnects as those formed by the manufacturing method A are fabricated.

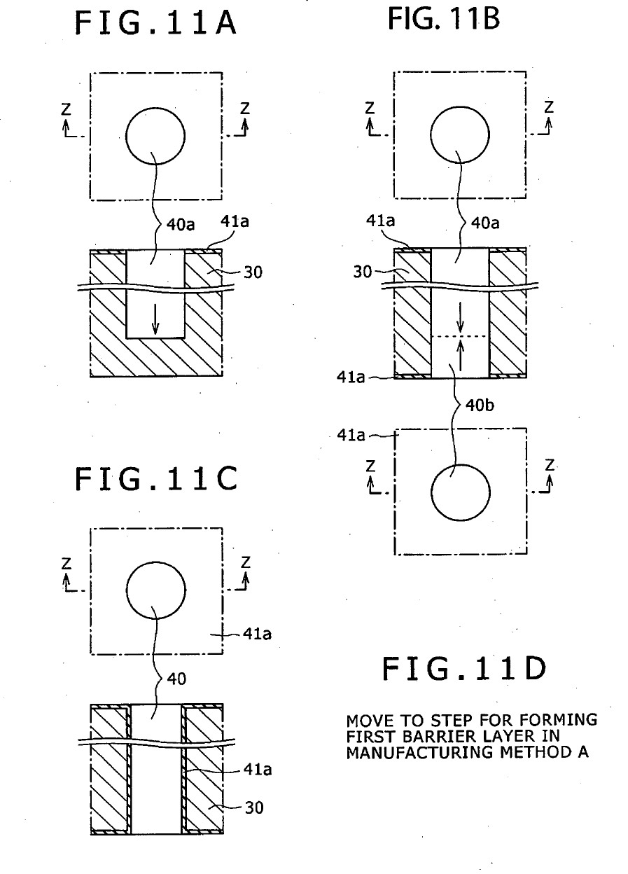

FIGS. 11A to 11D are diagrams for explaining a manufacturing method C for through-interconnects in a semiconductor chip according to an embodiment of the present invention. The upper drawings and the lower drawings of FIGS. 11A and 11C are plan views and sectional views along the line Z-Z, respectively. The upper drawing, the middle drawing, and the lower drawing of FIG. 11B are a plan view, a sectional view along the line Z-Z, and a lower face view, respectively.

The manufacturing method C shown in FIG. 11 is employed for the case where it is difficult to form a through-hole at a practical level by etching only from one face of a wafer. In this method C, etching is carried out from one face of a wafer to thereby form a first recess, followed by etching from the other face of the wafer for formation of a second recess. These first and second recesses are made to communicate with each other and thereby one through-hole having apertures on both the face sides of the wafer is formed (refer to Patent Document 5). This manufacturing method is applied to formation of a through-hole having an aperture diameter of 10 μm to 80 μm with use of a wafer having a thickness of 100 μm to 300 μm.

As shown in FIG. 11, in the manufacturing method C, a recess (second recess) 40b is formed from the back face instead of polishing from the back face, employed in the manufacturing method B. The second recess 40b is made to communicate with a recess (first recess) 40a formed from the front face, so that a through-hole 40 having apertures on both the front-face and back-face sides of a Si substrate 30. The above-described general dry etching or ICP-RIE can be applied to the formation of two recesses.

Specifically, as shown in FIG. 11A, a first insulating layer 41a is formed on the front face, followed by formation of a resist layer and exposure of the resist layer. Thereafter, the recess 40a is formed in the arrowhead direction by Si etching from the front face, followed by removal of the resist layer. Subsequently, as shown in FIG. 11B, the first insulating layer 41a is formed on the back face, followed by formation of a resist layer and exposure of the resist layer. Thereafter, the recess 40b is formed in the arrowhead direction by Si etching from the back face so that the through-hole 40 arising from communicating of two recesses 40a and 40b with each other is formed, followed by removal of the resist layer.

Subsequently, the first insulating layer 41a is formed also inside the through-hole 40 in such a manner as to be connected to the first insulating layers 41a on the front and back faces.

For subsequent steps, the manufacturing procedure proceeds to the step of forming the first barrier layer 42a in the manufacturing method A described with FIGS. 3 to 7 (see FIG. 4D and the above explanation relating to FIG. 4D).

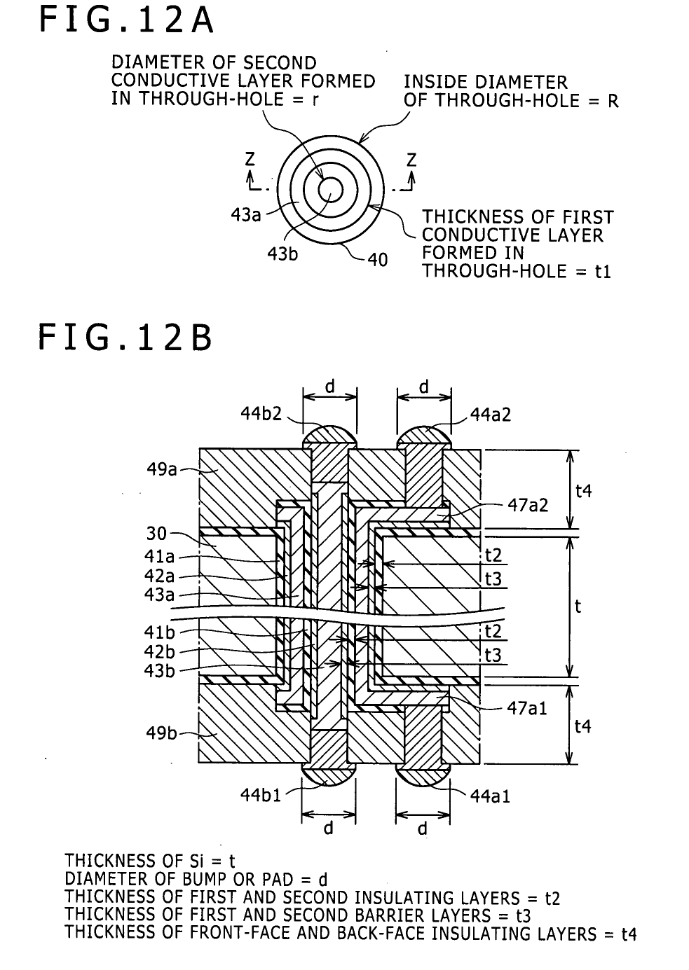

FIGS. 12A and 12B are diagrams for explaining a size example relating to through-interconnects in a semiconductor chip according to an embodiment of the present invention. FIG. 12A is a plan view, and FIG. 12B is a sectional view (enlarged view of FIG. 7D).

Referring to FIG. 12, when the thickness t of the silicon substrate (wafer) 30 is 0.1 mm to 0.15 mm and the diameter R of a through-hole is 50 μm for example, the aspect ratio of the through-hole is 2 to 3. An example of the sizes of the respective components for this through-hole is as follows: the thickness t1 of the first conductive layer is 10 μm; the diameter r of the second conductive layer is 20 μm; the thickness t2 of the first and second insulating layers is 2.4 μm; the thickness t3 of the first and second barrier layers is 0.1 μm; the thickness t4 of the front-face and back-face insulating layers is 3 μm; and the diameter d of the bumps or pads is 30 μm.

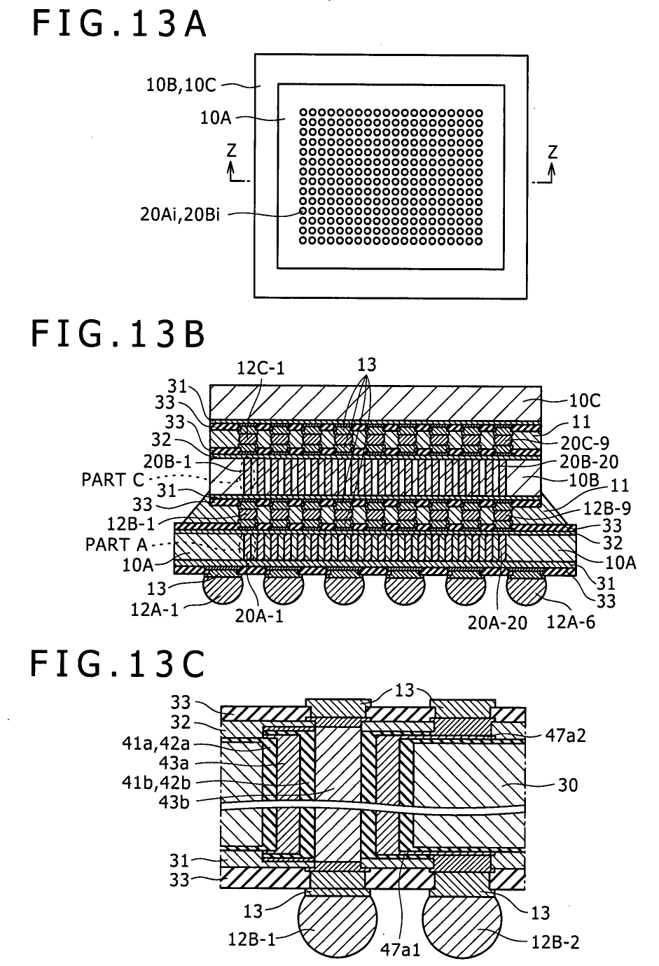

FIGS. 13A to 13C are diagrams for explaining the structure of another example of a semiconductor device formed by stacking chips having through-interconnects according to an embodiment of the invention. FIG. 13A is a plan view. FIG. 13B is a sectional view along the line Z-Z. FIG. 13C is an enlarged view around the part C (sectional view of interconnects coupled to the leftmost through-interconnect 20B-1).

The structure of a semiconductor chip 10A of the present embodiment is the same as that shown in FIG. 1, and through-interconnects having the same structure as that shown in FIG. 1 are formed in the semiconductor chip 10A. In a semiconductor chip 10B, through-interconnects 20Bj (j=1, 2, . . . , J (J is an integer number)) are formed inside through-holes that penetrate from an element and interconnect circuit layer 31 formed on the front-face side of a Si substrate 30 of the semiconductor chip 10B to a redistribution layer 32 and an insulating layer 33 formed on the back-face side of the Si substrate. In FIGS. 13A and 13B, through-interconnects arranged in a matrix of 14 rows by 20 columns are shown, and the through-interconnects 20B-1 to 20B-20 along the line Z-Z are shown, respectively.

As shown in FIG. 13C, the through-interconnect 20B-1 is formed of a first insulating layer 41a, a first barrier layer 42a, a first conductive layer 43a, a second insulating layer 41b, a second barrier layer 42b, and a second conductive layer 43b that are formed inside a through-hole.

The first conductive layer 43a is electrically coupled via an interconnect 47a1 formed on the front-face side of a Si substrate 30 to an electrode pad (over which a bump 12B-2 and a barrier metal 13 are formed). Furthermore, the first conductive layer 43a is electrically coupled via an interconnect 47a2 formed on the back-face side of the Si substrate 30 to an electrode pad (on which the barrier metal 13 is formed).

The second conductive layer 43b is electrically coupled to an electrode pad (over which a bump 12B-1 and the barrier metal 13 are formed) formed on the front-face side of the Si substrate 30. Furthermore, the second conductive layer 43b is electrically coupled to an electrode pad (on which the barrier metal 13 is formed) formed on the back-face side of the Si substrate 30.

As shown in FIGS. 13A and 13B, the semiconductor device of the present embodiment is an SiP formed by stacking the semiconductor chips 10A, 10B and 10C. The semiconductor chips 10A and 10B are electrically connected to each other via the through-interconnects 20Ai and bumps 12Bm (m=1, 2, . . . , M (M is an integer number), FIG. 13B shows only bumps 12B-1 to 12B-9 along the line Z-Z). An underfill material 11 serves to protect the connection part. The semiconductor chips 10B and 10C are electrically connected to each other via the through-interconnects 20Bj and bumps 12Cn (n=1, 2, . . . , N (N is an integer number), FIG. 13B shows only bumps 12C-1 to 12C-9 along the line Z-Z). The area between the semiconductor chips 10B and 10C is sealed by a known method called a no-flow underfill method or NCP process. Therefore, this SiP is constructed by combining three semiconductor chips 10A, 10B, and 10C in such a way that the connection parts are fixed and protected.

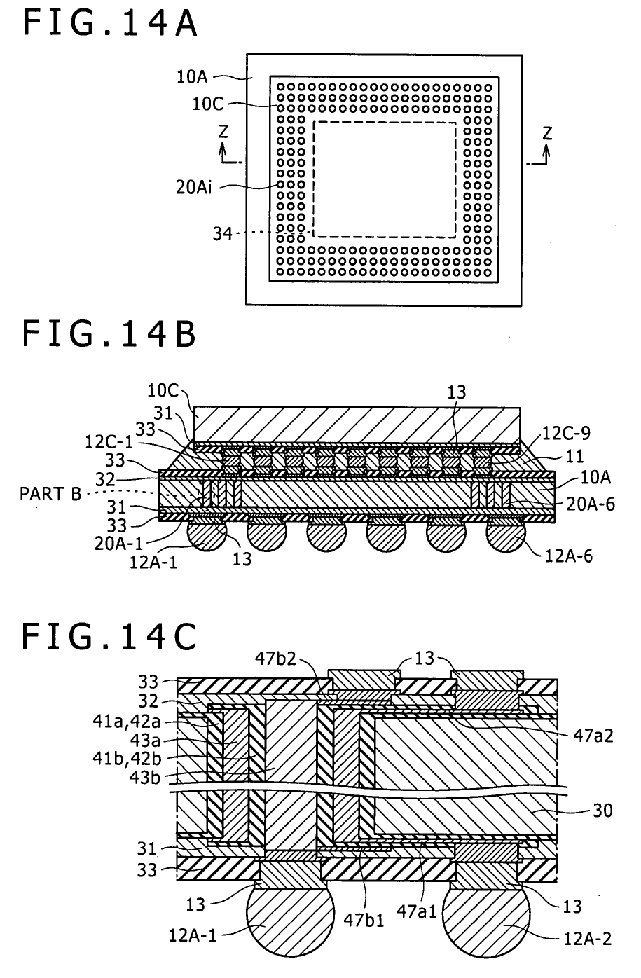

FIGS. 14A to 14C are diagrams for explaining the structure of another example of a semiconductor device formed by stacking chips having through-interconnects according to an embodiment of the invention. FIG. 14A is a plan view. FIG. 14B is a sectional view along the line Z-Z. FIG. 14C is an enlarged view around the part B (sectional view of interconnects coupled to the leftmost through-interconnect 20A-1).

The structures of semiconductor chips with through-interconnects and a semiconductor device formed of the chips shown in FIG. 14 are basically the same as those of the semiconductor chips with through-interconnects and the semiconductor device formed of the chips shown in FIG. 1. Therefore, only different points between these structures will be described below.

In a semiconductor chip 10A shown in FIG. 14, through-interconnects 20Ai (i=1, 2, . . . , (6×21+12×6), FIG. 14B shows only through-interconnects 20A-1 to 20A-6 along the line Z-Z) are formed in the chip region other than a formation region 34 for elements and interconnect circuits formed on the front-face side, i.e., formed in a chip peripheral region.

As shown in FIG. 14C, the through-interconnect 20A-1 is formed of a first insulating layer 41a, a first barrier layer 42a, a first conductive layer 43a, a second insulating layer 41b, a second barrier layer 42b, and a second conductive layer 43b that are formed inside a through-hole.

The first conductive layer 43a is electrically coupled via an interconnect 47a1 formed on the front-face side of a Si substrate 30 to an electrode pad (on which a barrier metal 13 having thereon a bump 12A-2 is formed). Furthermore, the first conductive layer 43a is electrically coupled via an interconnect 47a2 formed on the back-face side of the Si substrate 30 to an electrode pad (on which the barrier metal 13 is formed).

The second conductive layer 43b is electrically coupled to an electrode pad (on which the barrier metal 13 having thereon a bump 12A-1 is formed) formed on the front-face side of the Si substrate 30. Furthermore, the second conductive layer 43b is electrically coupled via an interconnect 47b2 formed on the back-face side of the Si substrate 30 to an electrode pad (on which the barrier metal 13 is formed).

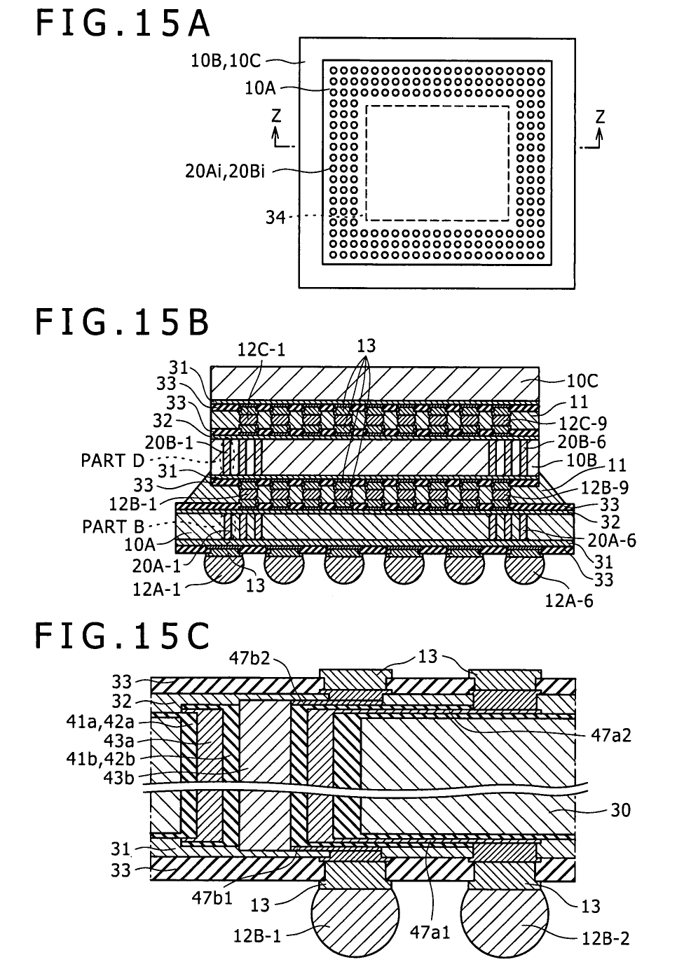

FIGS. 15A to 15C are diagrams for explaining the structure of another example of a semiconductor device formed by stacking chips having through-interconnects according to an embodiment of the invention. FIG. 15A is a plan view. FIG. 15B is a sectional view along the line Z-Z. FIG. 15C is an enlarged view around the part D (sectional view of interconnects coupled to the leftmost through-interconnect 20B-1).

The structures of semiconductor chips with through-interconnects and a semiconductor device formed of the chips shown in FIG. 15 are basically the same as those of semiconductor chips with through-interconnects and the semiconductor device formed of the chips shown in FIG. 13. Furthermore, a semiconductor chip 10A shown in FIG. 15 is basically the same as that shown in FIG. 13: through-interconnects 20Ai are formed in the chip region other than an interconnect circuit formation region 34, i.e., formed in a chip peripheral region. Therefore, only different points between these structures will be described below.

As shown in FIG. 15C, a through-interconnect 20B-1 is formed of a first insulating layer 41a, a first barrier layer 42a, a first conductive layer 43a, a second insulating layer 41b, a second barrier layer 42b, and a second conductive layer 43b that are formed inside a through-hole.

The first conductive layer 43a is electrically coupled via an interconnect 47a1 formed on the front-face side of a Si substrate 30 to an electrode pad (on which a barrier metal 13 having thereon a bump 12B-2 is formed). Furthermore, the first conductive layer 43a is electrically, coupled via an interconnect 47a2 formed on the back-face side of the Si substrate 30 to an electrode pad (on which the barrier metal 13 is formed).

The second conductive layer 43b is electrically coupled via an interconnect 47b1 formed on the front-face side of the Si substrate 30 to an electrode pad (on which the barrier metal 13 having thereon a bump 12B-1 is formed). Furthermore, the second conductive layer 43b is electrically coupled via an interconnect 47b2 formed on the back-face side of the Si substrate 30 to an electrode pad (on which the barrier metal 13 is formed).

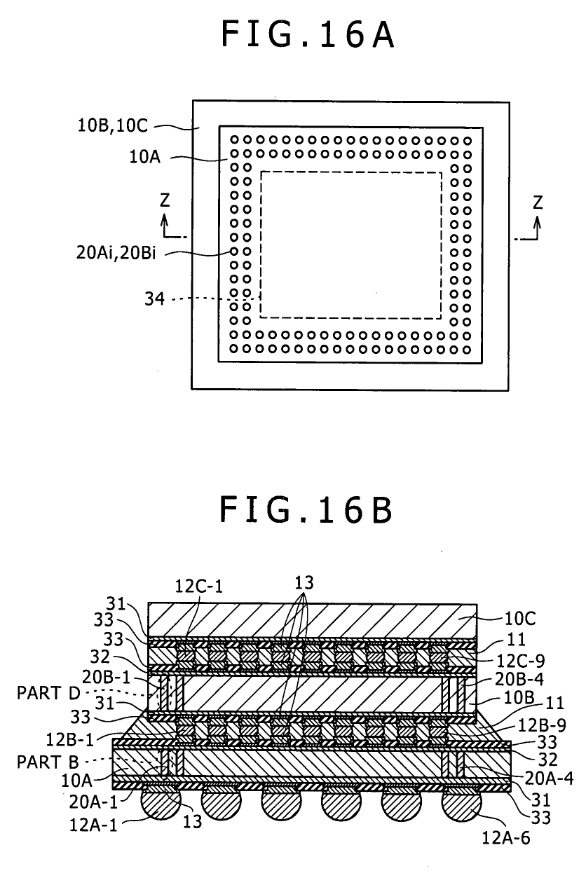

FIGS. 16A and 16B are diagrams for explaining the structure of another example of a semiconductor device formed by stacking chips having through-interconnects according to an embodiment of the invention. FIG. 16A is a plan view. FIG. 16B is a sectional view along the line Z-Z.

The structures of semiconductor chips with through-interconnects and a semiconductor device formed of the chips shown in FIG. 16 are basically the same as those of the semiconductor chips with through-interconnects and the semiconductor device formed of the chips shown in FIG. 15. Therefore, only different points between these structures will be described below.

In semiconductor chips 10A and 10B shown in FIG. 16, through-interconnects 20Ai and 20Bi (i=1, 2, . . . , (4×19+12×4), FIG. 16B shows only through-interconnects 20A-1 to 20A-4 and 20B-1 to 20B-4 along the line Z-Z) are formed in the chip region other than a formation region 34 for elements and interconnect circuits, i.e., formed in a chip peripheral region. The structures around the part B and the part D shown in FIG. 16B are the same as those shown in prior drawings.

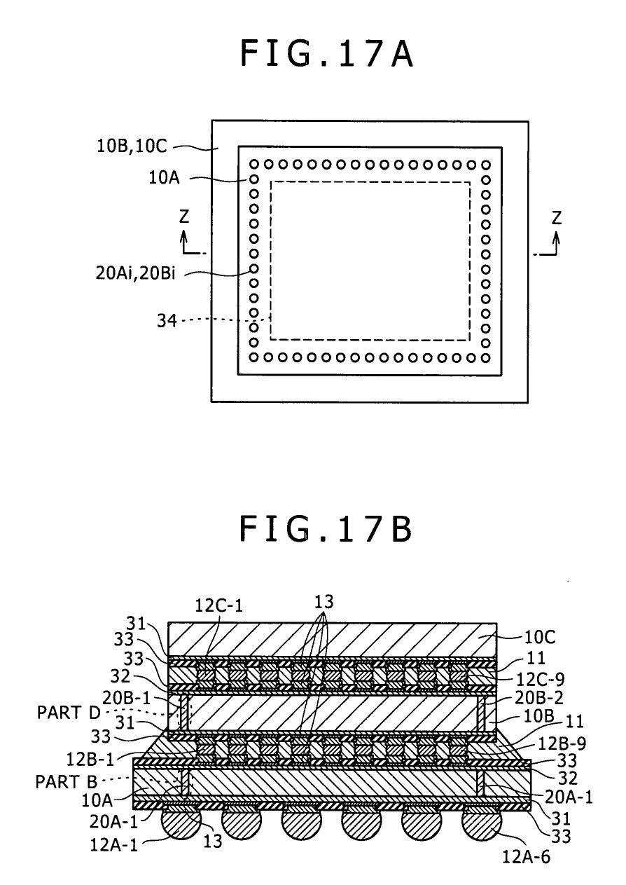

FIGS. 17A and 17B are diagrams for explaining the structure of another example of a semiconductor device formed by stacking chips having through-interconnects according to an embodiment of the invention. FIG. 17A is a plan view. FIG. 17B is a sectional view along the line Z-Z.

The structures of semiconductor chips with through-interconnects and a semiconductor device formed of the chips shown in FIG. 17 are basically the same as those of the semiconductor chips with through-interconnects and the semiconductor device formed of the chips shown in FIG. 16. Therefore, only different points between these structures will be described below.

In semiconductor chips 10A and 10B shown in FIG. 17, through-interconnects 20Ai and 20Bi (i=1, 2, . . . , (2×17+12×2), FIG. 17B shows only through-interconnects 20A-1, 20A-2, 20B-1, and 20B-2 along the line Z-Z) are formed in the chips region other than a formation region 34 for elements and interconnect circuits, i.e., formed in a chip peripheral region. The structures around the part B and the part D shown in FIG. 17B are the same as those shown in prior drawings.

In the examples shown in FIGS. 14 to 17, the number of through-interconnects formed in a chip peripheral region is set small for simplification of the drawings. The number of through-holes that can be formed in an actual semiconductor chip will be roughly estimated below. In particular, an estimation will be made as to the number of through-holes that can be formed in a chip peripheral region outside the formation region 34 for elements and interconnect circuits based on an assumption that through-holes are formed only in the chip peripheral region and through-interconnects are formed in the through-holes, although it is also possible to form electrode pads connected to conductive layers serving as through-interconnects on the substrate outer face in the formation region 34 for elements and interconnect circuits with intermediary of an insulating layer.

When the lengths of the sides of the formation region 34 for elements and interconnect circuits are L1 and L2, and the lengths of the sides of the entire chip are (L1+2Δ2) and (L2+2Δ1), the area of the region in which through-holes can be formed is {(L1×Δ1+L2×Δ2+2×Δ1×Δ2)}×2. This evaluation employs the following assumption: the diameter or side length of a through-hole having a circular or square shape is d (μm), and the arrangement distance between the through-holes in a square grid thereof is 2d. According to this assumption, the roughly estimated number N of through-holes that can be formed in the chip peripheral region outside the formation region 34 for elements and interconnect circuits is N=2(L1×Δ1+L2×Δ2+2×Δ1×Δ2)/(2d×2d). If n conductive layers are formed in one through-hole as through-interconnects to serve as signal transmission interconnect lines independent of each other, total n×N signal transmission interconnect lines can be ensured.

For example, N is 1100 when the respective parameters are as follows: L1=L2=5 (mm), Δ1=Δ2=0.5 (mm), and d=50 (μm). In this case, if the number n of through-interconnects formed in one through-hole is three based on an assumption that the total sum of the thicknesses of the insulating layer, barrier layer and conductive layer is about 10 μm, total 3300 signal transmission interconnect lines can be ensured.

Furthermore, N is 2400 when the respective parameters are as follows: L1=L2=5 (mm), Δ1=Δ2=1 (mm), and d=50 (μm). In this case, total 7200 signal transmission interconnect lines can be ensured if n is three.

As described above, in the above-described embodiments in which plural through-holes are formed in a chip peripheral region and plural through-interconnects are formed inside each through-hole, a sufficient number of through-interconnects can be formed merely by ensuring a small-area region for formation of through-holes in the chip peripheral region outside the formation region 34 for elements and interconnect circuits. In this structure, the chip size is small: it is slightly larger than the region 34. In addition, through-holes are not formed in the region 34, and hence there is no need to considerably change design for formation of elements in the region 34. Furthermore, through-holes can be formed in the region in which electrode pads on the premise of existing wire bonding are formed, and therefore it is sufficient to open the necessary number of through-holes in this region and form through-interconnects inside the through-holes. This eliminates the necessity of a large design change.

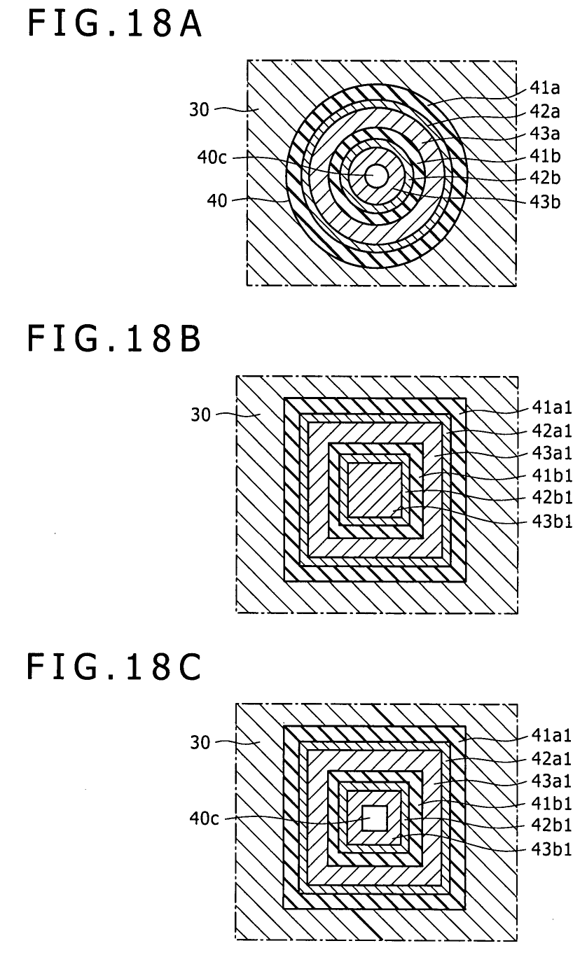

FIGS. 18, 19 and 20 are sectional views for explaining the structures of modifications of through-interconnects according to an embodiment of the present invention. These sectional views are along a plane perpendicular to the center axis of a through-hole that is actually opened or the center axis of a virtual through-hole that is not actually opened.

In a modification of through-interconnects shown in FIG. 18A, the space inside a second barrier layer 42b is not completely filled with a second conductive layer 43b, but a through-hole 40c is left in the second conductive layer 43b, unlike the through-interconnect structure shown in FIG. 2.

In a modification of through-interconnects shown in FIG. 18B, the following layers are formed along the inner periphery of a through-hole having a square shape: a first insulating layer 41a1, a first barrier layer 42a1, a first conductive layer 43a1, a second insulating layer 41b1, and a second barrier layer 42b1 that have a hollow square column shape, and a second conductive layer 43b1 having a square column shape.

In a modification of through-interconnects shown in FIG. 18C, the space inside a second barrier layer 42b1 is not completely filled with a second conductive layer 43b1, but a through-hole 40c is left in the second conductive layer 43b1, unlike the through-interconnect structure shown in FIG. 18B.

An SiP in which plural chips including the semiconductor chips shown in FIGS. 18A and 18C are stacked is mounted on an interposer substrate, followed by being sealed by insulating resin. Therefore, the through-holes 40c, which are left after formation of the second conductive layers 43b and 43b1 shown in FIGS. 18A and 18C, are also sealed by the resin.

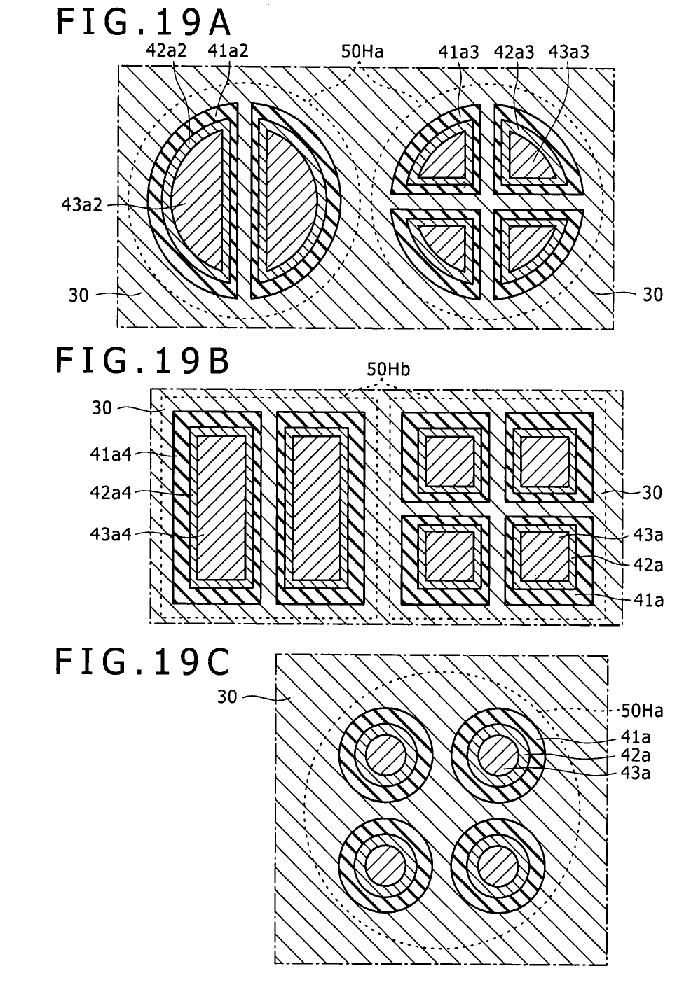

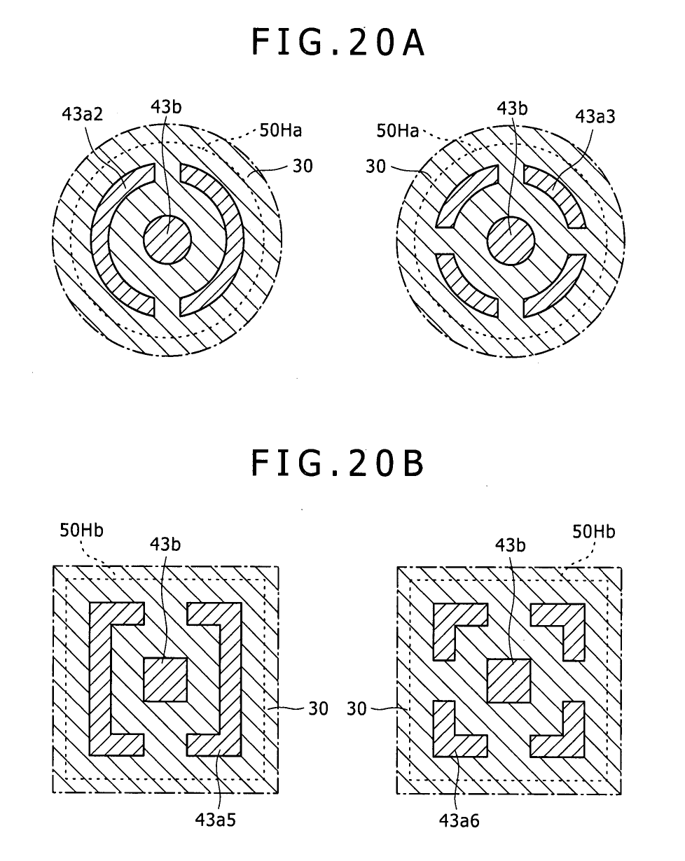

In modifications of through-interconnects shown in FIGS. 19 and 20, through-holes having various shapes are opened (formed) inside a virtual through-hole that is not actually formed, followed by formation of through-interconnects.

In an example shown in the left drawing of FIG. 19A, two through-holes each having a half circle shape are formed inside a virtual through-hole 50Ha having a circular shape. Formed inside each through-hole is a through-interconnect that has a substantially half cylinder shape as its whole shape and is formed of a first insulating layer 41a2, a first barrier layer 42a2, and a first conductive layer 43a2.

In an example shown in the right drawing of FIG. 19A, four through-holes each having a quarter circle shape are formed inside a virtual through-hole 50Ha having a circular shape. Formed inside each through-hole is a through-interconnect that has a substantially quarter cylinder shape as its whole shape and is formed of an insulating layer 41a3, a first barrier layer 42a3, and a first conductive layer 43a3.

In an example shown in the left drawing of FIG. 19B, two rectangular-column through-holes each having a rectangular planar shape are formed inside a virtual through-hole 50Hb having a rectangular shape. Formed inside each through-hole is a through-interconnect that has a rectangular column shape as its whole shape and is formed of a first insulating layer 41a4, a first barrier layer 42a4, and a first conductive layer 43a4.

In an example shown in the right drawing of FIG. 19B, four rectangular-column through-holes each having a square planar shape are formed inside a virtual through-hole 50Hb having a square shape. Formed inside each through-hole is a through-interconnect that has a rectangular column shape as its whole shape and is formed of a first insulating layer 41a, a first barrier layer 42a, and a first conductive layer 43a.

In an example shown in FIG. 19C, four whole circular through-holes are formed inside a virtual through-hole 50Ha having a circular shape. Formed inside each through-hole is a through-interconnect that has a whole circular shape as its whole shape and is formed of an insulating layer 41a, a first barrier layer 42a, and a first conductive layer 43a.

In an example shown in the left drawing of FIG. 20A, formed inside a virtual through-hole 50Ha having a circular shape are two through-holes each having a substantially half circular-ring shape and one cylinder through-hole surrounded by these two half circular-ring through-holes. A first conductive layer 43a2 is formed inside the half circular-ring through-holes, and a second conductive layer 43b is formed inside the cylinder through-hole.

In an example shown in the right drawing of FIG. 20A, formed inside a virtual through-hole 50Ha having a circular shape are four through-holes each having a substantially quarter circular-ring shape and one cylinder through-hole surrounded by these four quarter circular-ring through-holes. A first conductive layer 43a3 is formed inside the quarter circular-ring through-holes, and a second conductive layer 43b is formed inside the cylinder through-hole.

In an example shown in the left drawing of FIG. 20B, formed inside a virtual through-hole 50Hb having a square shape are two column through-holes each having a U-character planar shape and one square column through-hole. A first conductive layer 43a5 having a U-character planar shape is formed inside the U-shaped column through-holes, and a second conductive layer 43b is formed inside the square column through-hole.

In an example shown in the right drawing of FIG. 20B, formed inside a virtual through-hole 50Hb having a square shape are four column through-holes each having an L-character planar shape and one square column through-hole. A first conductive layer 43a6 having an L-character planar shape is formed inside the L-shaped column through-holes, and a second conductive layer 43b is formed inside the square column through-hole.

Note that in FIG. 20, illustration of first insulating layers 41a2, 41a3, 41a5, and 41a6, and first barrier layers 42a2, 42a3, 42a5, and 42a6 is omitted for simplification.

In the above-described embodiments, plural through-interconnects are formed in one through-hole. Therefore, even when the number of signals to be transmitted from the front-face side to the back-face side of a substrate is increased, there is no need to increase the number of through-holes, which can prevent a chip area increase and hence can suppress a chip cost increase. That is, a large number of through-interconnects necessary for signal transmission can be formed without an increase in the number of through-holes formed in a substrate.

A comparison between the related art and the embodiment will be made assuming that they are employed for the case where through-holes having the same aperture diameter are formed for transmission of M kinds of signals independent of each other for example. Specifically, when the related art is used for this case, M through-holes are formed and only one through-interconnect is formed inside each through-hole, so that M kinds of signals can be transmitted. In contrast, it is possible for the embodiment to form M/2 through-holes and form two through-interconnects inside each through-hole to thereby allow transmission of M kinds of signals. Therefore, the number of through-holes in the embodiment is half that in the related art, and hence the area necessary for the formation of the through-holes in the embodiment is half that in the related art. Consequently, in the case of forming the through-holes in the formation region 34 for elements and interconnect circuits (see FIGS. 1 and 13), the embodiment can offer higher design flexibility in particular. Furthermore, in the case of forming the through-holes in a region outside the formation region 34 for elements and interconnect circuits, the embodiment can offer a reduced chip area compared with by the related art.

In addition, the embodiment can eliminate the need to decrease the diameter and formation pitch of through-holes, and the thickness of a chip, and hence can contribute to enhancement in the processing yield and quality.

Plural through-interconnects formed in one through-hole in the embodiment can be used for various purposes. For example, when first and second conducive layers are formed on the outer side and the inner side, respectively, in a through-hole as described above, the first conductive layer can be used as a power supply line or GND line, while the second conductive layer can be used as a signal line. This configuration is effective as a countermeasure against crosstalk noise, which is caused when the distance between through-holes in which through-interconnects are formed is small. Moreover, this configuration can prevent leakage of electromagnetic fields into adjacent through-holes, and can stabilize electric impedance, which has advantageous effects also on high-speed signal transmission.

Furthermore, it is also possible to use both first and second conductive layers as signal lines and transmit a difference signal corresponding to the potential difference between the first and second conductive layers. This configuration allows use of lower voltage, an increase in the speed, and enhancement in noise resistance. The use of lower voltage leads to lower power consumption and offers faster clock rise-up, which leads also to speed increase. Because a signal is transmitted based on the potential difference between the first and second conductive layers and this potential difference has no relation to a reference voltage, noise resistance against fluctuation of signals that flow through a power supply line and a GND line can also be enhanced.

If the first and second conductive layers are used as a GND line and a power supply line, respectively, strengthened coupling between the power supply line and the GND line is achieved, and hence enhancement in power supply characteristics is expected. In addition, this configuration can reduce fluctuation of the power supply at the time of switching, and thus functions as a decoupling capacitor. That is, this configuration offers a so-called built-in function (e.g., a built-in capacitor). Furthermore, through-holes in which the first and second conductive layers are used as the GND line and the power supply line, respectively, may be arranged with a constant pitch in a peripheral region or inside region thereof on a semiconductor chip disposed on the lower side in an SiP. This configuration offers an effect of EMI shielding against the external.

In addition, when three or more plural conductive layers are formed inside a through-hole with intermediary of insulating layers, the following configuration is available. Specifically, some of these plural conductive layers are used as through-interconnects serving as GND lines, while the other conductive layers are used as through-interconnects serving as signal transmission interconnect lines (signal lines). Furthermore, the through-interconnects serving as signal lines and those serving as GND lines are disposed alternately so that the GND line may exist between two signal lines. This configuration can reduce crosstalk noise even if the signal lines are extremely close to each other.

This is the end of the description of embodiments of the present invention. It should be obvious that the present invention is not limited to the above-described embodiments but various modifications can be made based on the technical idea of the invention.

In the examples shown in FIGS. 1 and 13 to 17, the size of the semiconductor chip 10A is different from those of other semiconductor chips 10B and 10C stacked over the semiconductor chip 10A. However, the semiconductor chips 10A, 10B and 10C may have the same size. In this case, the side-fill method is not employed but a known method referred to as a no-flow underfill method or NCP process is employed for stacking of the semiconductor chips.

In the examples shown in FIGS. 13 and 15 to 17, the semiconductor chip 10B is electrically connected between the semiconductor chips 10A and 10C via through-interconnects. It is also possible to further stack between the semiconductor chips 10B and 10C a desired number of semiconductor chips in which through-interconnects are formed in the same manner as in the semiconductor chip 10B and electrically connect the stacked semiconductor chips via through-interconnects similarly to the structures of FIGS. 13 and 15 to 17.

In other words, a semiconductor chip stack structure formed by electrically connecting plural semiconductor chips via through-interconnects can be disposed and electrically connected between the semiconductor chips 10B and 10C shown in FIGS. 13 and 15 to 17. It should be obvious that in this structure, the areas of plural semiconductor chips stacked on the semiconductor chip 10A are equal to or smaller than that of the semiconductor chip 10A.

The following factors are not limited to the above-described examples: the size and thickness of a chip; the position of the region in which through-holes are formed on a chip; the number and arrangement of the through-holes in the region; the numbers of electrode pads, bump electrodes, and so on formed on a chip; the thicknesses, areas, materials, manufacturing methods, and so on of the respective layers for constructing through-interconnects. These factors may be optionally changed to desired ones according to need. For example, as the material of conductive layers, any of aluminum, tungsten, copper, silver, gold, or the like can be used. Furthermore, the conductive layers can be formed also by CVD or sputtering. In addition, a through-hole or recess can be formed in a substrate such as a Si substrate also by wet etching.

As described above, embodiments of the present invention can provide a semiconductor device that allows formation of a large number of through-interconnects necessary for signal transmission without an increase in the number of through-holes, and can provide also a method for manufacturing the same.

While the invention has been described with reference to specific embodiments, the description is illustrative and is not to be construed as limiting the scope of the invention. Various modifications and changes may occur to those skilled in the art without departing from the spirit and scope of the invention as defined by the appended claims.

What is claimed is:

1. A semiconductor device in which a semiconductor chip is mounted over a substrate, the device comprising
a plurality of through-interconnects configured to be formed inside each of through-holes that penetrate the substrate and be led from the semiconductor chip to a face of the substrate on an opposite side of the semiconductor chip.

2. The semiconductor device according to claim 1, wherein
an insulating layer for electrically insulating the plurality of through-interconnects from each other is formed in the through-hole.

3. The semiconductor device according to claim 1, wherein
the plurality of through-interconnects are concentric with each other.

4. The semiconductor device according to claim 1, wherein
the through-holes are formed in a peripheral region of the substrate or in a region inside the peripheral region of the substrate.

5. The semiconductor device according to claim 1, wherein
the substrate is a semiconductor substrate stacked over a semiconductor chip.

6. The semiconductor device according to claim 5, wherein
a plurality of the semiconductor substrates are stacked, and the through-holes and the through-interconnects are formed in each of the semiconductor substrates.

7. A method for manufacturing a semiconductor device, the method comprising the steps of:
forming through-holes that penetrate a substrate; and
forming a plurality of through-interconnects that penetrate the substrate inside each of the through-holes with intermediary of an electrically insulating layer between the through-interconnects.

8. The method for manufacturing a semiconductor device according to claim 7, wherein
in the forming a plurality of through-interconnects, the through-interconnect is formed on an inner peripheral surface of the through-hole by through-hole plating.
